(19) United States
(12) Patent Application Publication
(10) Pub. No.: US 2025/0207027 A1
(43) Pub. Date: Jun. 26, 2025

(54) QUANTUM DOT COMPLEX, DISPLAY DEVICE COMPRISING THE QUANTUM DOT COMPLEX AND MANUFACTURING METHOD FOR THE DISPLAY DEVICE

(71) Applicant: Samsung Display Co., Ltd., Yongin-si (KR)

(72) Inventors: KYUNGSIG LEE, Yongin-si (KR); JUO NAM, Yongin-si (KR); KAWON PAK, Yongin-si (KR); SEUNG-WON PARK, Yongin-si (KR); TAEKJOON LEE, Yongin-si (KR); SEUNGHEE JANG, Yongin-si (KR); JAEBOK CHANG, Yongin-si (KR)

(73) Assignee: Samsung Display Co., Ltd., Yongin-si (KR)

(21) Appl. No.: 18/891,116

(22) Filed: Sep. 20, 2024

(30) Foreign Application Priority Data
Dec. 20, 2023 (KR) 10-2023-0187623

(51) Int. Cl. C09K 11/88; B82Y 20/00; B82Y 40/00; C09K 11/02; C09K 11/08; H10K 50/115; H10K 59/38

(52) U.S. Cl. CPC C09K 11/883; C09K 11/025; C09K 11/0883; H10K 50/115; H10K 59/38; B82Y 20/00; B82Y 40/00

(57) ABSTRACT

A quantum dot complex includes a quantum dot, a shell surrounding the quantum dot, and nanoparticles bonded to a surface of the shell and including silver.

### CROSS-REFERENCE TO RELATED APPLICATION(S)

This application claims priority to and benefits of Korean Patent Application No. 10-2023-0187623 under 35 U.S.C. § 119, filed on Dec. 20, 2023, in the Korean Intellectual Property Office (KIPO), the entire contents of which are incorporated herein by reference.

### BACKGROUND

### 1. Technical Field

The disclosure herein relates to a quantum dot complex, a display device including the quantum dot complex, and a manufacturing method for the display device.

### 2. Description of the Related Art

Various display devices used in multimedia devices such as a television, a mobile phone, a tablet computer, a navigation device and a game console are being developed. A display device includes a display module including a self-luminous type light emitting element that displays an image by emitting light from a light emitting material.

In order to improve the color reproducibility of a display device, different types of light control layers may be included depending on pixels. The light control layer may transmit only light in a wavelength range or may convert light in other wavelength range. Development of light emitting elements using quantum dots as a light emitting material is in progress, and there is a need to improve the luminous efficiency and color characteristics of light emitting elements using quantum dots.

### SUMMARY

An object of the disclosure is to provide a quantum dot complex having high quantum yield.

Another object of the disclosure is to provide a display device having improved luminous efficiency by including a quantum dot complex.

Another object of the disclosure is to provide a method for manufacturing a display device having improved process stability.

A quantum dot complex according to an embodiment of the disclosure may include a quantum dot, a shell surrounding the quantum dot, and nanoparticles bonded to a surface of the shell and including silver.

In an embodiment, a thickness of the shell may be in a range of about 10 nm to about 50 nm.

In an embodiment, the shell may include at least one of a metal oxide and a polymer compound.

In an embodiment, the shell may include at least one of SiO₂, TiO₂, and polymethyl methacrylate (PMMA).

In an embodiment, a maximum absorption wavelength range of the nanoparticle may be in a range of about 400 nm to about 450 nm.

In an embodiment, a full width of half maximum of a maximum absorption wavelength range of the nanoparticle may be in a range of about 80 nm to about 120 nm.

In an embodiment, a maximum emission wavelength range of the quantum dot may be in a range of about 510 nm to about 550 nm.

In an embodiment, the quantum dot may include a core, and a middle shell surrounding the core.

In an embodiment, the core may include a first semiconductor nanocrystal, the middle shell may include a second semiconductor nanocrystal different from the first semiconductor nanocrystals, and each of the first semiconductor nanocrystal and the second semiconductor nanocrystal may include at least one of a group II-VI compound, a group III-VI compound, a group I-III-VI compound, a group III-V compound, a group III-II-V compound, a group IV-VI compound, a group IV element, a group IV compound, and a combination thereof.

In an embodiment, the core may include InP or AgInGaS.

In an embodiment, the middle shell may include a first middle shell surrounding the core, and a second middle shell surrounding the first middle shell, and each of the first middle shell and the second middle shell may include a group III-VI compound.

A method for manufacturing a display device according to an embodiment of the disclosure may include preparing a display panel, and forming a light control layer on the display panel by forming multiple light control parts. The forming of at least one of the multiple light control parts may include providing a quantum dot composition including a base resin and a quantum dot complex dispersed in the base resin to form a preliminary light control part, and curing the preliminary light control part. The quantum dot complex may include a quantum dot, a shell surrounding the quantum dot, and nanoparticles bonded to a surface of the shell and including silver.

In an embodiment, a viscosity of the quantum dot composition may be less than or equal to about 25 cps.

In an embodiment, the method may further include forming a preliminary light control member after the curing of the preliminary light control part, and exposing the preliminary light control part to excited light in a wavelength of about 450 nm. After the exposing of the preliminary light control part, an external quantum efficiency (EQE) may be greater than or equal to about 30%.

In an embodiment, a content of the quantum dot complex may be in a range of about 20 wt % to about 45 wt % on a basis of a total quantum dot composition content.

In an embodiment, a thickness of the shell may be in a range of about 10 nm to about 50 nm.

In an embodiment, the shell may include at least one of SiO₂, TiO₂, and polymethyl methacrylate (PMMA).

In an embodiment, a maximum absorption wavelength range of the nanoparticle may be in a range of about 400 nm to about 450 nm.

In an embodiment, a maximum emission wavelength range of the quantum dot may be in a range of about 510 nm to about 550 nm.

A display device according to an embodiment of the disclosure may include a display panel, and a light conversion layer disposed on the display panel and including multiple light control parts. At least one of the multiple light control parts may include a quantum dot complex, and the quantum dot complex includes a quantum dot, a shell surrounding the quantum dot, and nanoparticles bonded to a surface of the shell and including silver.

In an embodiment, the display panel may include a light emitting element producing first light, and the multiple light control parts may include a first light control part transmitting the first light, a second light control part converting the first light into second light, and a third light control part converting the first light into third light.

### BRIEF DESCRIPTION OF THE DRAWINGS

The accompanying drawings are included to provide a further understanding of the disclosure and are incorporated in and constitute a part of this specification. The drawings illustrate embodiments of the disclosure and, together with the description, serve to explain principles of the disclosure. In the drawings:

FIG. 1 is a perspective view of an electronic device of an embodiment of the disclosure;

FIG. 2 is an exploded perspective view of an electronic device of an embodiment of the disclosure;

FIG. 3 is a schematic cross-sectional view of a display device according to an embodiment of the disclosure, corresponding to line I-I′ in FIG. 1;

FIG. 4 is an enlarged plan view of a portion of a display device according to an embodiment of the disclosure;

FIG. 5A is a schematic cross-sectional view of a display device according to an embodiment of the disclosure;

FIG. 5B is a schematic diagram illustrating the structure of a quantum dot according to an embodiment of the disclosure;

FIG. 6 is a graph showing light absorbance in accordance with the wavelength of metal nanoparticles;

FIG. 7 is a schematic cross-sectional view of a display device according to another embodiment of the disclosure;

FIG. 8A is a schematic cross-sectional view of a display device according to another embodiment of the disclosure;

FIG. 8B is a schematic cross-sectional view of a light emitting element according to an embodiment of the disclosure;

FIG. 9 is a graph showing luminous intensity in accordance with the wavelength of the Examples and Comparative Example;

FIG. 10A is a flowchart showing a method for manufacturing a display device according to an embodiment of the disclosure;

FIG. 10B is a flowchart detailing a step of forming a light control layer according to an embodiment of the disclosure; and

FIG. 11A to 11C are schematic cross-sectional views showing some steps in the method for manufacturing a display device according to an embodiment of the disclosure.

### DETAILED DESCRIPTION OF THE EMBODIMENTS

Hereinafter, embodiments of the disclosure will be explained referring to the drawings.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Like reference numerals refer to like elements throughout. In the drawings, the thicknesses, ratios, and dimensions of elements are exaggerated for effective explanation of technical contents. In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure. As used herein, the singular forms are intended to include the plural forms as well, unless the context clearly indicates otherwise.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In the description, when a layer, a film, a region, a plate, etc. is referred to as being “directly on” another part, it can mean no intervening layers, films, regions, plates, etc. are present. For example, being “directly on” may mean disposition without using an additional element such as an adhesive element between two layers or two elements.

In the description, “group” may be a group in the periodic table of elements.

In the description, “group II” may include group IIA and group IIB, and examples of group II metal may include Cd, Zn, Hg and Mg, without limitation.

In the description, “group III” may include group IIIA and group IIIB, and examples of group III metal may include Al, In, Ga and Tl, without limitation.

In the description, “group IV” may include group IVA and group IVB, and examples of group IV metal may include Si, Ge and Sn, without limitation.

In the description, “group I” may include group IA and group IB, and may include Li, Na, K, Rb and Cs, without limitation.

In the description, “group V” may include group VA and may include nitrogen, phosphor, arsenic, antimony and bismuth, without limitation.

In the description, “group VI” may include group VIA and may include sulfur, selenium and tellurium, without limitation.

In the description, the term “metal” may also include metalloids such as Si.

Unless otherwise defined, all terms (including technical and scientific terms) used herein have the same meaning as commonly understood by one of ordinary skill in the art to which this disclosure belongs. In addition, it will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a quantum dot complex according to an embodiment of the disclosure, a light emitting element and a display device including the same will be explained referring to the drawings.

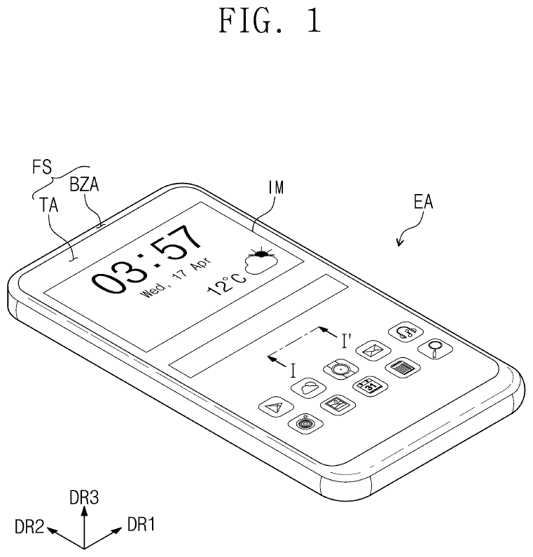

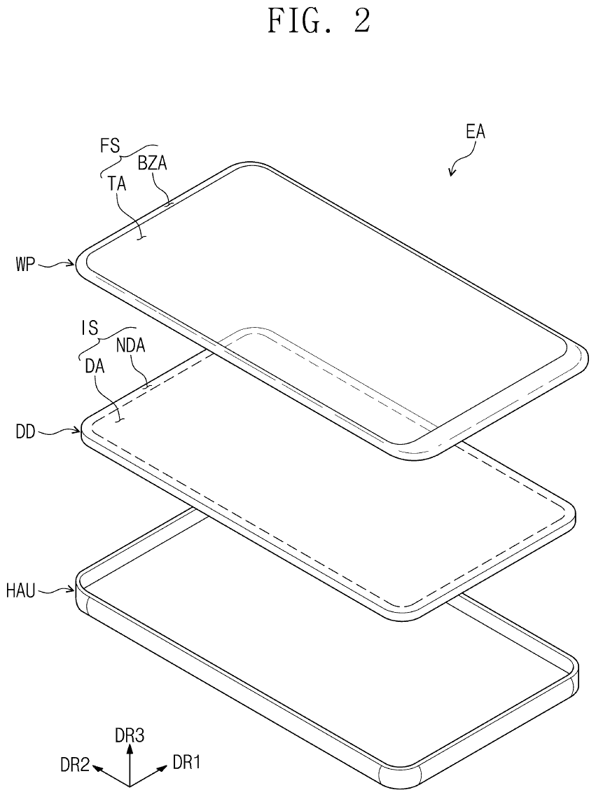

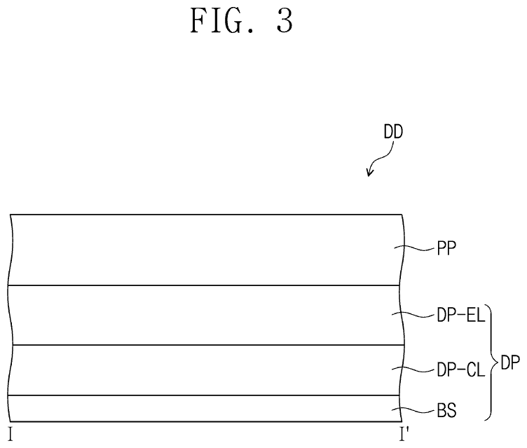

FIG. 1 is a perspective view of an embodiment of an electronic device EA. FIG. 2 is an exploded perspective view of an electronic device EA of an embodiment. FIG. 3 is a schematic cross-sectional view of a display device DD according to an embodiment of the disclosure, corresponding to line I-I′ in FIG. 1.

In an embodiment, an electronic device EA may be a large-sized electronic device such as a television, monitor and an external billboard. In an embodiment, the electronic device EA may be a small- or medium-sized electronic device such as a personal computer, a laptop computer, a personal digital device, a car navigation unit, a game console, a smart phone, a tablet, and a camera. However, the disclosure is not limited thereto, and the electronic device EA may be employed as other electronic devices as long as they do not deviate from the disclosure. In FIG. 1, a smart phone is illustrated as an embodiment of the electronic device EA.

The electronic device EA may include a display device DD and a housing HAU. The display device DD may display image IM through a display surface IS, and a user may view the image provided through a transparent area TA corresponding to the front surface FS of the electronic device EA. The image IM may include static image as well as dynamic image. In FIG. 1, the front surface FS is shown as being parallel to a plane defined by a first direction DR1 and a second direction DR2 which intersects the first direction DR1. However, the disclosure is not limited thereto, and in another embodiment, the front surface FS of the electronic device EA may have a curved shape.

The normal direction of the front surface FS of the electronic device EA, for example, the direction in which the image IM is displayed, such as a thickness direction of the electronic device EA, may be indicated by a third direction. The front surface (or top) and the rear surface (or bottom) of each member may be distinguished by the third direction DR3. The directions indicated by the first to third directions DR1, DR2 and DR3 may have relative concept and may be converted to another directions.

Although not shown in the drawings, the electronic device EA may include a foldable display device including a folding area and a non-folding area, or a bending display device including at least one bending part.

The electronic device EA may include a display device DD and a housing HAU. In the electronic device EA, the front surface FS may correspond to the front surface of the display device DD and may correspond to the front surface of a window WP. Accordingly, the front surface of the electronic device EA, the front surface of the display device DD, and the front surface of the window WP may be indicated by a same reference symbol FS.

The housing HAU may accommodate the display device DD. The housing HAU may cover the display device DD and expose the top of the display surface IS of the display device DD. The housing HAU may cover the side surface and the bottom of the display device DD and expose the entire top. However, the disclosure is not limited thereto, and the housing HAU may cover a portion of the top as well as the side surface and the bottom of the display device DD.

In the electronic device EA of an embodiment, a window WP may include an optically transparent insulating material. The window WP may include a transparent area TA and a bezel area BZA. The front surface FS of the window WP including the transparent area TA and the bezel area BZA may correspond to the front surface FS of the electronic device EA.

In FIG. 1 and FIG. 2, the transparent area TA is shown as a square shape with rounded corners in a plan view. However, the disclosure is not limited thereto, and the transparent area TA may have various shapes and is not limited to any one embodiment.

The transparent area TA may be an optically transparent area. The bezel area BZA may be an area having a relatively low light transmittance compared to the transparent area TA. The bezel area BZA may have a color. The bezel area BZA may be adjacent to the transparent area TA and may surround the transparent area TA in a plan view. The bezel area BZA may define the shape of the transparent area TA. However, the disclosure is not limited to the illustration, and the bezel area BZA may be disposed adjacent to only one side of the transparent area TA, or some portion of the bezel area BZA may be omitted.

The display device DD may be disposed below the window WP. In the description, “below” may mean the opposite direction to the direction in which the display device DD provides images.

In an embodiment, the display device DD may be a configuration substantially producing image IM. The image IM produced from the display device DD may be displayed on a display surface IS and viewed by a user at the outside through the transparent area TA. The display device DD may include a display area DA and a non-display area NDA. The display area DA may be an area activated according to electrical signals. The non-display area NDA may be an area covered by the bezel area BZA. The non-display area NDA may be adjacent to the display area DA. The non-display area NDA may surround the display area DA in a plan view.

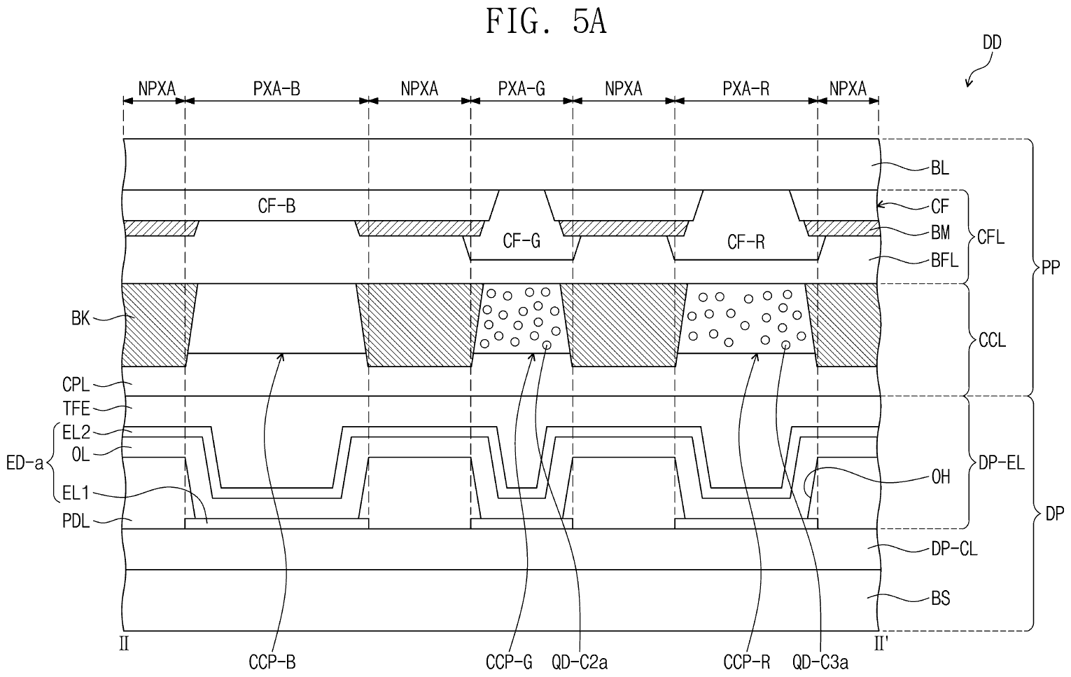

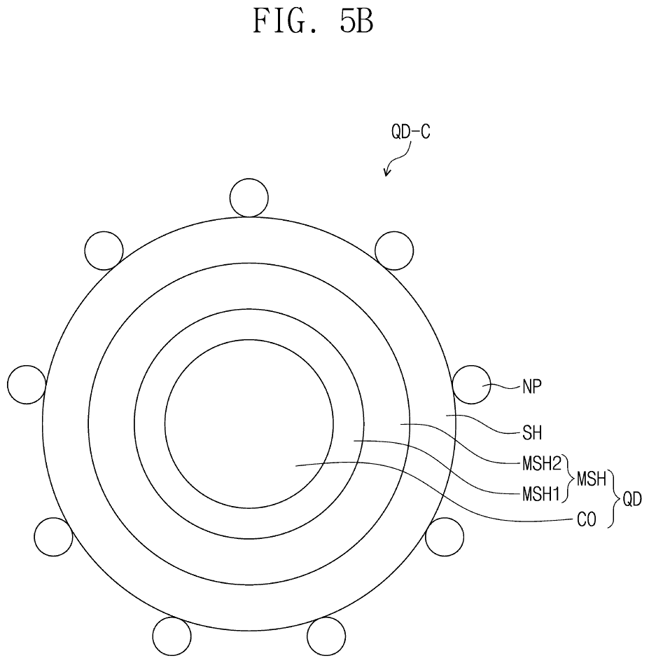

Referring to FIG. 3, the display device DD may include a display panel DP and a light control layer PP disposed on the display panel DP. The display panel DP may include a display element layer DP-EL. The display element layer DP-EL may include a light emitting element ED-a (FIG. 5A).

The light control layer PP may be disposed on the display panel DP and control reflected light from the display panel DP by external light. The light control layer PP may include, for example, a polarization layer or a color filter layer.

In the display device DD of an embodiment, the display panel DP may be an emission type display panel. For example, the display panel DP may be a quantum dot light emitting display panel including a quantum dot light emitting element. However, the disclosure is not limited thereto.

The display panel DP may include a base substrate BS, a circuit layer DP-CL disposed on the base substrate BS, and a display element layer DP-EL disposed on the circuit layer DP-CL.

The base substrate BS may be a member providing a base surface on which the display element layer DP-EL is disposed. The base substrate BS may be a glass substrate, a metal substrate, a plastic substrate or the like. However, the disclosure is not limited thereto, and the base substrate BS may be an inorganic substrate, an organic substrate, or a composite material substrate. The base substrate BS may be a flexible substrate which may be readily bent or folded.

In an embodiment, the circuit layer DP-CL may be disposed on the base substrate BS, and the circuit layer DP-CL may include multiple transistors (not shown). Each of the transistors (not shown) may include a control electrode, an input electrode, and an output electrode. For example, the circuit layer DP-CL may include a switching transistor and a driving transistor for driving the light emitting element ED-a (FIG. 5A) of the display element layer DP-EL.

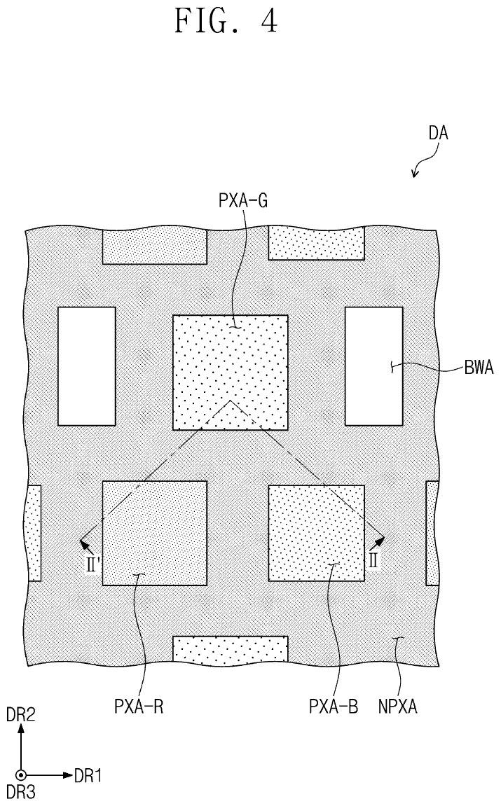

FIG. 4 is an enlarged plan view of a portion of a display device DD according to an embodiment of the disclosure. FIG. 5A is a schematic cross-sectional view of a display device DD according to an embodiment of the disclosure. FIG. 5A shows a portion corresponding to line II-II′ in FIG. 4. FIG. 5B is a schematic diagram illustrating the structure of a quantum dot according to an embodiment of the disclosure.

Referring to FIG. 4 and FIG. 5A, the display device DD may include a peripheral area NPXA and light emitting areas PXA-B, PXA-G and PXA-R. Each of the light emitting areas PXA-B, PXA-G and PXA-R may be an area emitting light produced in the light emitting element ED-a. The light emitting areas PXA-B, PXA-G and PXA-R may be separated from each other in a plan view.

The light emitting areas PXA-B, PXA-G and PXA-R may be divided into multiple groups according to the color of emitted light. In the display device DD according to an embodiment, as shown in FIG. 4 and FIG. 5A, three light emitting areas PXA-B, PXA-G and PXA-R may emit blue light, green light and red light. For example, the display device DD of an embodiment may include a first light emitting area PXA-B, a second light emitting area PXA-G and a third light emitting area PXA-R, distinguished from each other. In the description, the first light emitting area PXA-B may be a blue light emitting area, the second light emitting area PXA-G may be a green light emitting area, and the third light emitting area PXA-R may be a red light emitting area.

In FIG. 4, the first to third light emitting areas PXA-B, PXA-G and PXA-R are shown to have the same shape and different areas in a plan view, but the disclosure is not limited thereto. The areas of at least two or more among the first to third light emitting areas PXA-B, PXA-G and PXA-R may be the same. The areas of the first to third light emitting areas PXA-B, PXA-G and PXA-R may be designed based on the color of light emitted. Among the primary colors, the area of a pixel area emitting green light may be the largest, and the area of a pixel area emitting blue light may be the smallest.

The light emitting areas PXA-B, PXA-G and PXA-R may be areas distinguished by a pixel definition layer PDL. The peripheral area NPXA may be areas between the light emitting areas PXA-B, PXA-G and PXA-R and may be an area corresponding to the pixel definition layer PDL. In the description, each of the light emitting areas PXA-B, PXA-G and PXA-R may correspond to a pixel. The light emitting element ED-a may be disposed and distinguished in an opening part OH defined by the pixel definition layer PDL.

In FIG. 4, the first to third light emitting areas PXA-B, PXA-G and PXA-R are shown to have a rectangular shape in a plan view, but the disclosure is not limited thereto. In a plan view, the first to third light emitting areas PXA-B, PXA-G and PXA-R may have different polygonal shapes such as a rhombus and pentagon. In another embodiment, each of the first to third light emitting areas PXA-B, PXA-G and PXA-R may have a rectangular shape with rounded corners in a plan view.

FIG. 4 illustrates that the second light emitting area PXA-G is arranged in the first row, and the first light emitting area PXA-B and the third light emitting area PXA-R are arranged in the second row. However, the disclosure is not limited thereto, and the arrangement of the first to third light emitting areas PXA-B, PXA-G and PXA-R may vary diversely. For example, the first to third light emitting areas PXA-B, PXA-G and PXA-R may be arranged in a same row.

One of the first to third light emitting areas PXA-B, PXA-G and PXA-R may emit first color light, another one of the first to third light emitting areas PXA-B, PXA-G and PXA-R may emit second color light different from the first color light, and the remaining one of the first to third light emitting areas PXA-B, PXA-G and PXA-R may emit light of a third color light which is different from the first color light and the second color light. In an embodiment, the first light emitting area PXA-B may emit first light corresponding to a portion of a source light. For example, the third light emitting area PXA-R may emit red light, the second light emitting area PXA-G may emit green light, and the first light emitting area PXA-B may emit blue light.

In the display area DA, a bank well area BWA may be defined. The bank well area BWA may be an area formed for preventing defects due to mis-alignment during the patterning process of multiple light control parts CCP-R, CCP-G and CCP-B included in a light conversion layer CCL, which will be described below. The bank well area BWA may be an area formed by removing a portion of a partition wall part BK. In FIG. 4, two bank well areas BWA formed adjacent to the second light emitting area PXA-G are shown according to an embodiment. But the disclosure is not limited thereto, and the shape and arrangement of the bank well areas BWA may vary diversely.

Referring to FIG. 5A, a display device DD of an embodiment may include a display panel DP and a light control layer PP disposed on the display panel DP. The light control layer PP may include a light conversion layer CCL disposed on the display panel DP. In an embodiment, the light control layer PP may further include a color filter layer CFL. The color filter layer CFL may be disposed between a base layer BL and the light conversion layer CCL.

The display panel DP may be an emission type display panel. For example, the display panel DP may be an organic electroluminescence display panel or a quantum dot light emitting display panel.

The display panel DP may include a base substrate BS, a circuit layer DP-CL provided on the base substrate BS and a display element layer DP-EL.

The base substrate BS may be a member providing a base surface on which the display element layer DP-EL is disposed. The base substrate BS may be a glass substrate, a metal substrate, a plastic substrate or the like. However, the disclosure is not limited thereto, and the base substrate BS may be an inorganic substrate, an organic substrate, or a composite material substrate. The base substrate BS may be a flexible substrate which may be readily bent or folded.

In an embodiment, the circuit layer DP-CL may be disposed on the base substrate BS, and the circuit layer DP-CL may include multiple transistors (not shown). Each of the transistors (not shown) may include a control electrode, an input electrode, and an output electrode. For example, the circuit layer DP-CL may include a switching transistor and a driving transistor for driving the light emitting element ED of the display element layer DP-EL.

The display element layer DP-EL may include a light emitting element ED-a as a display element. The light emitting element ED-a may produce the above-described source light and may include an emission layer disposed over a first light emitting area PXA-B, a second light emitting area PXA-G and a third light emitting area PXA-R.

The display element layer DP-EL may include a pixel definition layer PDL. The pixel definition layer PDL may be an organic layer or an inorganic layer. At least a portion of the light emitting element ED-a may be disposed in an opening part defined in the pixel definition layer PDL.

The pixel definition layer PDL may be formed using a polymer resin. For example, the pixel definition layer PDL may include a polyacrylate-based resin or a polyimide-based resin. In an embodiment, the pixel definition layer PDL may further include an inorganic material in addition to the polymer resin. The pixel definition layer PDL may include a light absorbing material, a black pigment, or black dye. The pixel definition layer PDL including a black pigment or black dye may form a black pixel definition layer. During forming of the pixel definition layer PDL, carbon black or the like may be used as a black pigment or black dye, but the disclosure is not limited thereto.

In an embodiment, the pixel definition layer PDL may be formed using an inorganic material. For example, the pixel definition layer PDL may include silicon nitride (SiNₓ), silicon oxide (SiOₓ), silicon oxynitride (SiOₓN_{y}) or the like. The pixel definition layer PDL may define the light emitting areas PXA-B, PXA-G and PXA-R. By the pixel definition layer PDL, the light emitting areas PXA-B, PXA-G and PXA-R and the peripheral area NPXA may be divided.

The display element layer DP-EL may include the light emitting element ED-a, and the light emitting element ED-a may include a first electrode EL1, a second electrode EL2 and multiple layers OL disposed between the first electrode EL1 and the second electrode EL2. The multiple layers OL may include a hole transport region, an emission layer and an electron transport region. On the light emitting element ED-a, an encapsulation layer TFE may be disposed.

In the light emitting element ED-a included in the display panel DP of an embodiment, the emission layer may include a host and a dopant, which are organic electroluminescence light emitting materials, or include the above-described quantum dot according to an embodiment. In the display panel DP of an embodiment, the light emitting element ED-a may emit blue light.

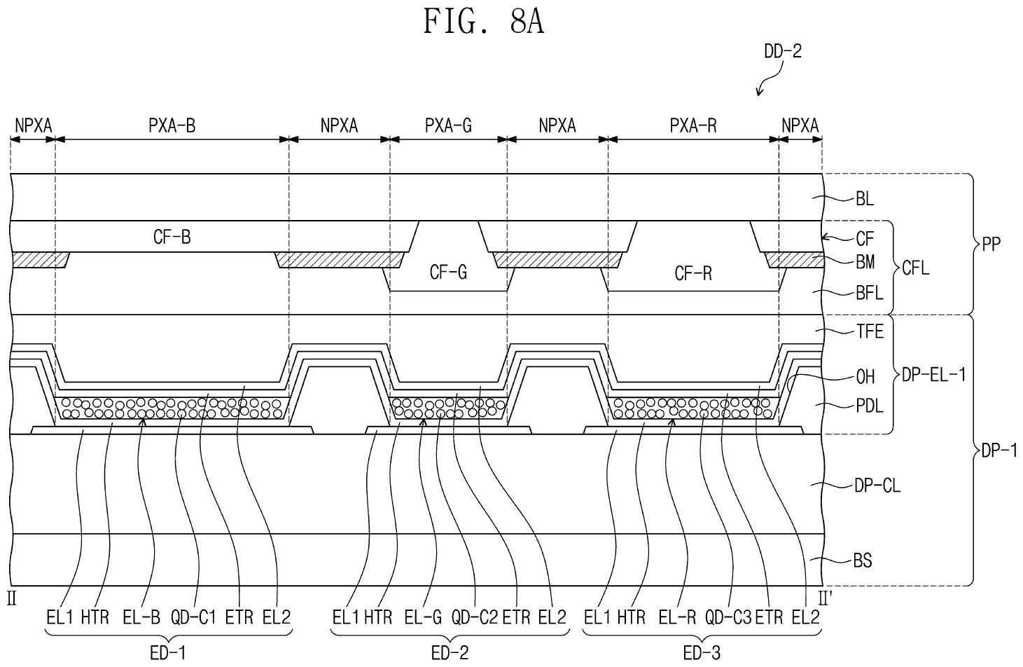

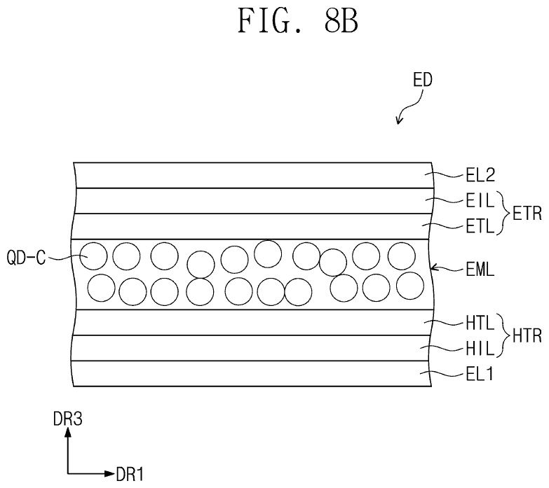

In the light emitting element ED-a included in the display panel DP of an embodiment, a hole transport region and an electron transport region may be disposed, which will be explained below with reference to FIG. 8B.

The encapsulation layer TFE may cover the light emitting element ED-a. The encapsulation layer TFE may be a single layer or a stacked layer of multiple layers. The encapsulation layer TFE may be a thin film encapsulation layer. The encapsulation layer TFE may protect the light emitting element ED-a. The encapsulation layer TFE may cover the top of the light emitting element ED-a disposed in the opening part OH and may fill the opening part OH.

On the encapsulation layer TFE, the light control layer PP may be disposed. The light control layer PP may include the light conversion layer CCL, the color filter layer CFL and the base layer BL.

The light conversion layer CCL may include multiple partition wall parts BK spaced apart from each other, and light control parts CCP-B, CCP-G and CCP-R disposed between the partition wall parts BK. The partition wall part BK may include a polymer resin and a liquid repellent additive. The partition wall part BK may include a light absorbing material, or a black pigment or black dye. For example, the partition wall part BK may include a black pigment or black dye and may form a black partition wall part. During forming of the black partition wall part, carbon black or the like may be used as a black pigment or black dye, but the disclosure is not limited thereto.

The multiple light control parts CCP-B, CCP-G and CCP-R may be disposed between the partition wall part BK, and at least a portion of the light control parts CCP-B, CCP-G and CCP-R may change the optical properties of a source light.

The light conversion layer CCL may include a first light control part CCP-B transmitting first light which is a source light, a second light control part CCP-G including a first quantum dot complex QD-C2a converting the first light into second light, and a third light control part CCP-R including a second quantum dot complex QD-C3a converting the first light into third light. The second light may be light in a wavelength region higher than the first light, and the third light may be light in a wavelength region higher than the first light and the second light. For example, the first light may be blue light, the second light may be green light, and the third light may be red light.

The first light control part CCP-B of the light conversion layer CCL may not include a quantum dot complex. However, the disclosure is not limited thereto, and in another embodiment, the first light control part CCP-B of the light conversion layer CCL may include a quantum dot complex. The quantum dot complex included in the first light control part CCP-B may emit blue light which is the first color light.

At least one of the quantum dot complexes QD-C2a and QD-C3a, included in the light control parts CCP-B, CCP-G and CCP-R may be a quantum dot complex according to an embodiment, which will be explained below. In an embodiment, the first quantum dot complex QD-C2a may be a quantum dot complex according to an embodiment, which will be explained below. However, the disclosure is not limited thereto, and each of the first and second quantum dot complexes QD-C2a and QD-C3a may be a quantum dot complex according to an embodiment, which will be explained below.

In an embodiment, the first and second quantum dot complexes QD-C2a and QD-C3a included in the second and third light control parts CCP-G and CCP—R may be formed from different core materials. In another embodiment, the first and second quantum dot complexes QD-C2a and QD-C3a may be formed from a same core material.

In an embodiment, the first and second quantum dot complexes QD-C2a and QD-C3a may have different diameters. For example, the first quantum dot complex QD-C2a in the second light control part CCP-G which emits light in a shorter wavelength range may have an average diameter smaller than the second quantum dot complex QD-C3a of the third light control part CCP-R which emits light in a longer wavelength range.

In the description, an average diameter may be an arithmetic average value of the diameters of quantum dot particles. The diameter of the quantum dot particles may be an average value of the widths on the cross-sections of the quantum dot particles.

The relation between the average diameters of the first and second quantum dot complexes QD-C2a and QD-C3a is not limited to the above-described limitation. For example, in FIG. 5A, the sizes of the first and second quantum dot complexes QD-C2a and QD-C3a are shown similar, but in another embodiment, the sizes of the first and second quantum dot complexes QD-C2a and QD-C3a included in the light control parts CCP-G and CCP-R may be different from each other. In an embodiment, the average diameter of two quantum dot complexes selected from the first and second quantum dot complexes QD-C2a and QD-C3a may be similar, and the remainder may be different.

The light control parts CCP-B, CCP-G and CCP-R each may further include a scatterer. The scatterer may be an inorganic particle. For example, the scatterer may include at least one of TiO₂, ZnO, Al₂O₃, SiO₂, and hollow silica. The scatterer may include at least one of TiO₂, ZnO, Al₂O₃, SiO₂, and hollow silica, or a mixture of two or more materials selected among TiO₂, ZnO, Al₂O₃, SiO₂, and hollow silica.

Each of the light control parts CCP-B, CCP-G and CCP-R may include a base resin dispersing the quantum dot complexes QD-C2a and QD-C3a and/or the scatterer. The base resin may be a medium in which the quantum dot complexes QD-C2a and QD-C3a and/or the scatterer are dispersed, and may be composed of various resin compositions which may generally be referred to as a binder. For example, the base resin may include an acrylic resin, a methacrylic resin, a urethane-based resin, a fluorine-based resin, an epoxy-based resin, a vinyl-based resin, a polyester-based resin, a polyamide-based resin, a polyimide-based resin, a cellulose-based resin, a perylene-based resin, a silicon-based resin or a combination thereof. The base resin may be a transparent resin.

The light conversion layer CCL may further include a filling layer CPL. The filling layer CPL may be disposed on the light control parts CCP-B, CCP-G and CCP-R and the partition wall part BK. The filling layer CPL may be disposed between the encapsulation layer TFE and the light control parts CCP-B, CCP-G and CCP-R. The filling layer CPL may block penetration of humidity and/or oxygen (hereinafter, referred to as “humidity/oxygen”). The filling layer CPL may be disposed on the light control parts CCP-B, CCP-G and CCP-R to block the exposure of the light control parts CCP-B, CCP-G and CCP-R to humidity/oxygen. The filling layer CPL may include at least one inorganic layer.

In an embodiment shown in FIG. 5A, the light control layer PP may include a color filter layer CFL. For example, the display device DD of an embodiment may further include a color filter layer CFL disposed on the light emitting element ED-a of the display panel DP.

In the display device DD of an embodiment, the light control layer PP may include a base layer BL and a color filter layer CFL.

The base layer BL may be a member providing a base surface on which the color filter layer CFL or the like is disposed. The base layer BL may be a glass substrate, a metal substrate, a plastic substrate or the like. However, the disclosure is not limited thereto, and the base layer BL may be an inorganic layer, an organic layer or a composite material layer.

The color filter layer CFL may include a light blocking part BM and a color filter part CF. The color filter part CF may include multiple filters CF-B, CF-G and CF-R. For example, the color filter layer CFL may include a first filter CF-B transmitting first light, a second filter CF-G transmitting second light, and a third filter CF-R transmitting third light. For example, the first filter CF-B may be a blue filter, the second filter CF-G may be a green filter, and the third filter CF-R may be a red filter.

Each of the filters CF-B, CF-G and CF-R may include a polymer photosensitive resin and a pigment or dye. The first filter CF-B may include a blue pigment or dye, the second filter CF-G may include a green pigment or dye, and the third filter CF-R may include a red pigment or dye.

However, the disclosure is not limited thereto, and in another embodiment, the first filter CF-B may not include a pigment or dye. The first filter CF-B may include a polymer photosensitive resin and may not include a pigment or dye. The first filter CF-B may be transparent. The first filter CF-B may be formed from a transparent photosensitive resin.

The light blocking part BM may be a black matrix. The light blocking part BM may include an organic light blocking material or an inorganic light blocking material, including a black pigment or black dye. The light blocking part BM may prevent light leakage phenomenon and may divide the boundary between adjacent filters CF-B, CF-G and CF-R.

The color filter layer CFL may further include a buffer layer BFL. For example, the buffer layer BFL may be a protection layer protecting the filters CF-B, CF-G and CF-R. The buffer layer BFL may be an inorganic material layer including at least one inorganic material among silicon nitride, silicon oxide and silicon oxynitride. The buffer layer BFL may be composed of a single layer or multiple layers.

In an embodiment shown in FIG. 5A, the first filter CF-B of the color filter layer CFL is shown to overlap the second filter CF-G and the third filter CF-R in a plan view, but the disclosure is not limited thereto. For example, the first to third filters CF-B, CF-G and CF-R may be divided by the light blocking part BM and may not overlap each other. In an embodiment, each of the first to third filters CF-B, CF-G and CF-R may be disposed corresponding to each of the blue light emitting area PXA-B, the green light emitting area PXA-G and the red light emitting area PXA-R.

In another embodiment, the display device DD of an embodiment may include a polarization layer (not shown) instead of the color filter layer CFL as the light control layer PP. The polarization layer (not shown) may block external light provided to the display panel DP from the outside. The polarization layer (not shown) may block a portion of the external light.

In an embodiment, the polarization layer (not shown) may reduce reflected light produced from the display panel DP by the external light. For example, the polarization layer (not shown) may block reflected light in a case where light provided from the outside of the display device DD enters the display panel DP and is emitted again. The polarization layer (not shown) may be a circular polarizer with an anti-reflection function, or the polarization layer (not shown) may include a linear polarizer and a λ/4 phase retarder. The polarization layer (not shown) may be disposed on the base layer BL and exposed, or the polarization layer (not shown) may be disposed below the base layer BL.

FIG. 5B is a schematic diagram illustrating the structure of a quantum dot complex according to an embodiment of the disclosure.

Referring to FIG. 5B, a quantum dot complex QD-C may include a quantum dot QD, a shell SH and nanoparticles NP. The shell SH may entirely surround the quantum dot QD. The quantum dot QD may include a core CO and a middle shell MSH. The middle shell MSH may be disposed between the quantum dot QD and the shell SH.

The quantum dot QD may be a semiconductor nanocrystal including at least one of a group II-VI compound, a group III-VI compound, a group I-III-VI compound, a group III-V compound, a group III-II-V compound, a group IV-VI compound, a group IV element, a group IV compound, and a combination thereof.

The group II-VI compound may include: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and mixtures thereof; or a combination thereof.

The group III-VI compound may include: a binary compound such as In₂S₃, and In₂Se₃; a ternary compound such as InGaS₃, and InGaSe₃; or a combination thereof.

The group I-III-VI compound may include: a ternary compound selected from the group consisting of AgInS, AgInS₂, CuInS, CuInS₂, AgGaS₂, CuGaS₂ CuGaO₂, AgGaO₂, AgAlO₂ and mixtures thereof; a quaternary compound such as AgInGaS₂, and CuInGaS₂; or a combination thereof.

The group III-V compound may include: a binary compound selected from the group consisting of GaN, GaP, GaAs, GaSb, AlN, AIP, AlAs, AlSb, InN, InP, InAs, InSb and mixtures thereof; a ternary compound selected from the group consisting of GaNP, GaNAs, GaNSb, GaPAs, GaPSb, AlNP, AlNAs, AlNSb, AlPAs, AlPSb, InGaP, InAIP, InNP, InNAs, InNSb, InPAs, InPSb and mixtures thereof; a quaternary compound selected from the group consisting of GaAINP, GaAlNAs, GaAINSb, GaAlPAs, GaAlPSb, GaInNP, GaInNAs, GaInNSb, GalnPAs, GalnPSb, InAINP, InAINAs, InAINSb, InAlPAs, InAlPSb and mixtures thereof; and a combination thereof. The group III-V compound may further include group II metals. For example, InZnP or the like may be selected as a group III—II-V compound.

The group IV-VI compound may include: a binary compound selected from the group consisting of SnS, SnSe, SnTe, PbS, PbSe, PbTe and mixtures thereof; a ternary compound selected from the group consisting of SnSeS, SnSeTe, SnSTe, PbSeS, PbSeTe, PbSTe, SnPbS, SnPbSe, SnPbTe and mixtures thereof; and a quaternary compound selected from the group consisting of SnPbSSe, SnPbSeTe, SnPbSTe and mixtures thereof; or a combination thereof. The group IV element may include Si, Ge and a mixture thereof. The group IV compound may include a binary compound selected from the group consisting of SiC, SiGe and a mixture thereof.

A binary compound, a ternary compound and a quaternary compound may be present in a particle at uniform concentration, or may be present in a particle at partially different concentration distribution. In an embodiment, the quantum dot QD may have a core/middle shell structure in which a quantum dot surrounds another quantum dot. In the core/middle shell structure, concentration gradient in which the concentration of a material that is present in the middle shell may decrease toward the core.

In embodiments, the quantum dot may have a core-middle shell structure including a core including the above-described nanocrystals and a middle shell surrounding the core. The middle shell of the quantum dot may play the role of a protecting layer for preventing the chemical deformation of the core and maintaining semiconductor properties and/or a charging layer for imparting the quantum dot with electrophoretic properties. The middle shell may have a single layer or multiple layers.

The middle shell MSH and the core CO may include different materials. For example, the core CO may include a first semiconductor nanocrystal, and the middle shell MSH may include a second semiconductor nanocrystal which is different from the first semiconductor nanocrystal. In an embodiment, the middle shell MSH may include a metal oxide or a nonmetal oxide. The middle shell MSH may include a metal oxide, a nonmetal oxide, a semiconductor nanocrystal, or a combination thereof.

The middle shell MSH may be composed of a single material, but may be formed to have concentration gradient. For example, the middle shell MSH may have concentration gradient in which the concentration of the second semiconductor nanocrystals present in the middle shell MSH decreases toward the core CO, and the concentration of the first semiconductor nanocrystals included in the core CO increases toward a center of the core CO.

In an embodiment, the middle shell MSH may have a multilayer structure. For example, the middle shell MSH may include a first middle shell MSH1 adjacent to the core CO, and a second middle shell MSH2 spaced apart from the core CO. The second middle shell MSH2 may be spaced apart from the core CO with the first middle shell MSH1 interposed between the second middle shell MSH2 and the core CO. The first middle shell MSH1 may surround the core CO, and the second middle shell MSH2 may surround the first middle shell MSH1. The second middle shell MSH2 may entirely surround the first middle shell MSH1. Accordingly, the surface of the quantum dot QD may be defined by the exterior surface of the second middle shell MSH2. The first middle shell MSH1 may be covered with the second middle shell MSH2 and may not be exposed from the quantum dot QD.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb or the like. However, the disclosure is not limited thereto.

The quantum dot may have a full width of half maximum (FWHM) of an emission wavelength spectrum less than or equal to about 45 nm. For example, the quantum dot may have a full width of half maximum (FWHM) of an emission wavelength spectrum less than or equal to about 40 nm. For example, the quantum dot may have a full width of half maximum (FWHM) of an emission wavelength spectrum less than or equal to about 30 nm. Within this range, color purity or color reproducibility may be improved, and light emitted via such quantum dot may be emitted in all directions, and light view angle may be improved.

A shape of the quantum dot is not particularly limited. For example, a shape of a quantum dot may be spherical, pyramidal, multi-arm, cubic nanoparticle, nanotube, nanowire, nanofiber, nanoplate particles, etc.

The color of light emitted from a quantum dot QD may be controlled according to a particle size of the quantum dot QD, and accordingly, a quantum dot QD may emit light of various colors including blue, red and green. If a particle size of a quantum dot QD decreases, the quantum dot QD may emit light in a short wavelength range. For example, for the quantum dots QD having a same core, the particle size of the quantum dot emitting green light may be smaller than the particle size of the quantum dot emitting red light. For the quantum dots QD having a same core, the particle size of the quantum dot QD emitting blue light may be smaller than the particle size of the quantum dot emitting green light. However, the disclosure is not limited thereto, and for the quantum dots QD having a same core, the particle size may be controlled depending on a material for forming a shell, a thickness of the shell or the like.

If the quantum dot QD emits various colors of light such as blue, red and green, the quantum dot QD having different emission colors may have different core materials.

In an embodiment, the core CO may include a group III-V compound or a group I-III-VI compound. For example, the core CO may include InP or AgInGaS. The quantum dot QD of an embodiment may include a core CO including a group III-V compound or a group I-III-VI compound and may have high blue light absorption.

In an embodiment, the quantum dot QD may be a non-Cd based quantum dot. For example, the quantum dot may not include cadmium (Cd).

The absorption wavelength of the core CO may be in a range of about 350 nm to about 530 nm. Accordingly, the core CO may absorb blue light in the above-described wavelength range and may emit green light or red light. The emission wavelength of the light emitted from the quantum dot QD may be controlled by controlling the size of the core CO, the thickness of the shell SH or the like.

In an embodiment, the quantum dot QD may emit light having an emission wavelength in a range of about 510 nm to about 550 nm. For example, the quantum dot QD may emit green light having an emission wavelength in a range of about 510 nm to about 550 nm. However, the disclosure is not limited thereto, and in another embodiment, the quantum dot QD may emit light having an emission wavelength in a range of about 630 nm to about 680 nm. For example, the quantum dot QD may emit red light having an emission wavelength in a range of about 630 nm to about 680 nm. The quantum dot QD may emit light having a target emission wavelength by controlling the amounts of elements included in the core CO.

In an embodiment, a diameter of the quantum dot QD may be in a range of about 1 nm to about 10 nm.

If a quantum dot QD satisfies the above-described average particle diameter range, characteristic behavior as a quantum dot QD may be obtained, and the quantum dot QD may have excellent dispersibility. By diversely selecting the average particle diameter of the quantum dots QD within the above-described range, the emission wavelength of the quantum dot QD and/or the semiconductor properties of the quantum dot may vary diversely.

The shell SH may surround the quantum dot QD. The shell SH may completely cover the quantum dot QD. Accordingly, in the quantum dot complex QD-C, the quantum dot QD may not be exposed to the outside. The shell SH may be disposed between the quantum dot QD and the nanoparticle NP and may block the contact between the quantum dot QD and the nanoparticle NP.

In an embodiment, the shell SH may include at least one of a metal oxide and a polymer compound.

The shell SH may include a metal oxide. The shell SH may be a layer composed of a metal oxide. The shell SH may include a metal oxide such as silicon oxide (SiO₂), titanium oxide (TiO₂), zinc oxide (ZnO₂), tin oxide (SnO₂), and zirconium oxide (ZrO₂).

In an embodiment, the shell SH may include at least one of silicon oxide (SiO₂), titanium oxide (TiO₂), zinc oxide (ZnO₂), tin oxide (SnO₂), and zirconium oxide (ZrO₂).

In an embodiment, the shell SH may include at least one of silicon oxide (SiO₂), and titanium oxide (TiO₂). For example, the shell SH may be composed of silicon oxide (SiO₂), or may be composed of titanium oxide (TiO₂).

In an embodiment, the shell SH may include a polymer compound. In an embodiment, the shell SH may include at least one of polymethyl methacrylate (PMMA), polycarbonate (PC), a cyclo-olefin polymer (COP), polyethylene terephthalate (PET), polyurethane (PU), polyethersulfone (PES), and polyethylene naphthalate (PEN). For example, the shell SH may include polymethyl methacrylate.

The shell SH may have a single layer structure or a multilayer structure. If the shell SH has a single layer structure, the shell SH may be composed of a single material or multiple materials. In case that the shell SH has a multilayer structure, the shell SH may be composed of different materials.

A thickness of the shell SH may be controlled to a range for increasing the surface plasmon resonance effect of the nanoparticles NP, which will be explained below. In an embodiment, a thickness of the shell SH may be in a range of about 10 nm to about 50 nm. For example, the thickness of the shell SH may be in a range of about 20 nm to about 30 nm. If the thickness of the shell SH is less than about 10 nm, a quenching phenomenon may occur due to nanoparticles NP, which may reduce the light amplification effect by the surface plasmon resonance shape. In case that the thickness of the shell SH is greater than about 50 nm, the distance between the quantum dot QD and the nanoparticle NP increases too much, and the surface plasmon resonance phenomenon may be reduced. If the thickness of the shell SH satisfied the above-described range, the quenching phenomenon due to the nanoparticles NP may be prevented, the surface plasmon resonance phenomenon may be optimized, and the light emission efficiency of the quantum dot QD may increase.

The shell SH may be disposed between the quantum dot QD and the nanoparticle NP and may keep the distance between the quantum dot QD and the nanoparticle NP within a range. If the quantum dot QD contacts the nanoparticle NP, quenching may occur due to the nanoparticle NP. According to an embodiment of the disclosure, by disposing the shell SH having a thickness between the quantum dot QD and the nanoparticle NP, the quenching phenomenon by the nanoparticle NP may be prevented, and the surface plasmon resonance effect by the nanoparticle NP may be improved, thereby increasing luminous efficiency. In the description, the “surface plasmon resonance” may be a collective vibration phenomenon of electrons, which occurs on the surface of a metal if light with a specific wavelength is incident on the metal.

On the surface of the shell SH, the nanoparticles NP may be disposed. The nanoparticle NP may include a metal having surface plasmon resonance. In FIG. 5B, the shape of the nanoparticle NP is shown spherical as an embodiment, but the disclosure is not limited thereto. For example, the nanoparticle NP may have diverse shapes such as oval, rod, hemisphere, diamond and an irregular shape.

In the quantum dot complex QD-C, the nanoparticle NP may be attached to the surface of the shell SH so that at least partial light emitted from the quantum dot QD may be coupled with the surface plasmon of the nanoparticle NP. For example, the nanoparticle NP may improve the luminous efficiency of the quantum dot QD through the surface plasmon resonance phenomenon.

The type of the nanoparticle NP may be appropriately selected depending on the type of the quantum dot QD. In an embodiment, the nanoparticle NP may include a metal with low light absorption with respect to a green light wavelength range and a red light wavelength range. For example, the nanoparticle NP may include a metal with low light absorption with respect to a wavelength range of about 500 nm to about 700 nm. In an embodiment, the nanoparticle NP may include a metal with a maximum absorption wavelength peak in a wavelength range of about 350 nm to about 490 nm. Since the nanoparticle NP includes a metal with low light absorption in a wavelength range of about 500 nm to about 700 nm, surface plasmon resonance phenomenon may increase, and accordingly, the luminous efficiency of the quantum dot QD may be further improved.

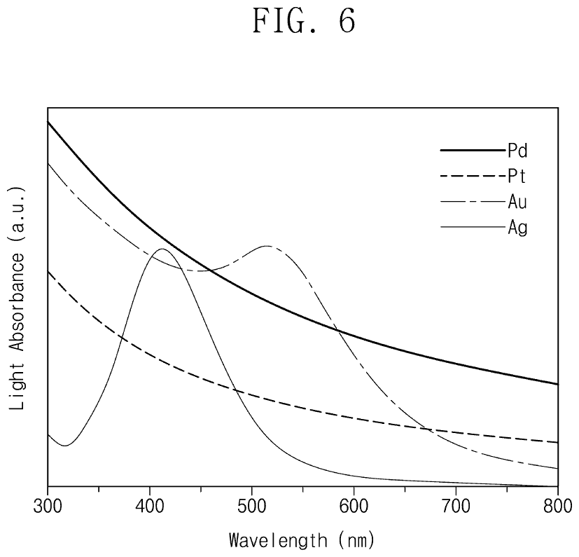

FIG. 6 is a graph showing light absorbance in accordance with the wavelength of metal nanoparticles. In FIG. 6, the absorption spectrums of palladium (Pd), platinum (Pt), gold (Au) and silver (Ag) nanoparticles are shown. The diameter of each nanoparticle used for measuring the absorption spectrum in FIG. 6 is in a range of about 3 nm to about 20 nm.

Referring to FIG. 6, it can be confirmed that the absorption spectrums of the metal nanoparticles are different depending on the materials. In the graph of FIG. 6, it can be confirmed that the absorption spectrum of silver (Ag) nanoparticles has a maximum absorption peak wavelength in a range of about 400 nm to about 450 nm. In contrast, it can be confirmed that the absorption spectrums of palladium (Pd), platinum (Pt) and gold (Au) nanoparticles have higher absorbance in wavelength range of about 500 nm or more. In the disclosure, a display device with improved visibility may be provided by including nanoparticles NP containing silver (Ag) as a metal that causes surface plasmon resonance. In the case of the silver (Ag) nanoparticles, light absorption of a visible light wavelength range of about 500 nm to about 700 nm is relatively small, and the overlap between an emission spectrum emitted from the quantum dot and the absorption spectrum of the nanoparticles NP may decrease, and thus, the transmittance of a target wavelength may be improved.

In an embodiment, the diameter of the nanoparticles NP may be in a range of about 3 nm to about 20 nm. If the diameter of the nanoparticles NP satisfies the above-described range, the absorption peak wavelength of the nanoparticles NP may be controlled in a target range, and the plasmon resonance effect may be improved.

Though not shown, the quantum dot complex QD-C may further include a ligand. In the quantum dot complex QD-C, a ligand may be attached to the surface of the shell SH. The quantum dot complex QD-C may have modified surface properties by the attachment of the ligand. The ligand may be bonded to the surface of the shell SH constituting the surface of the quantum dot complex QD-C.

In the description, the term “substituted or unsubstituted” may describe a group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the listed substituents may itself be substituted or unsubstituted. For example, a biphenyl group may be interpreted as an aryl group, or it may be interpreted as a phenyl group substituted with a phenyl group.

In the description, examples of a halogen atom may include a fluorine atom, a chlorine atom, a bromine atom or an iodine atom.

In the description, an alkyl group may be linear, branched, or cyclic. The number of carbon atoms in an alkyl group may be 1 to 50, 1 to 30, 1 to 20, 1 to 10, or 1 to 6. Examples of an alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl or the like, but the disclosure is not limited thereto.

In the description, an aryl group may be a functional group or substituent derived from an aromatic hydrocarbon ring. The aryl group may be monocyclic or polycyclic. The number of ring-forming carbon atoms in an aryl group may be 6 to 30, 6 to 20, or 6 to 15. Examples of an aryl group may include phenyl, naphthyl, fluorenyl, anthracenyl, phenanthryl, biphenyl, terphenyl, quaterphenyl, quinquephenyl, sexiphenyl, triphenylenyl, pyrenyl, benzofluoranthenyl, chrysenyl or the like, but the disclosure is not limited thereto.

In the description, a heteroaryl group may include at least one of B, O, N, P, Si, and S as heteroatoms. If a heteroaryl group includes two or more heteroatoms, the two or more heteroatoms may be the same as or different from each other. A heteroaryl group may be monocyclic or polycyclic. The number of ring-forming carbon atoms in a heteroaryl group may be 2 to 30, 2 to 20, or 2 to 10. Examples of a heteroaryl group may include thiophene, furan, pyrrole, imidazole, pyridine, bipyridine, pyrimidine, triazine, triazole, acridyl, pyridazine, pyrazinyl, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzoimidazole, benzothiazole, benzocarbazole, benzothiophene, dibenzothiophene, thienothiophene, benzofuran, phenanthroline, thiazole, isooxazole, oxazole, oxadiazole, thiadiazole, phenothiazine, dibenzosilole, dibenzofuran or the like, but the disclosure is not limited thereto.

In the description, a hydroxyl group may be a substituent having a “—OH” structure.

In the description, a thiol group may be a substituent having a “—SH” structure.

In the description, a thio group may include an alkyl thio group and an aryl thio group. The thio group may be the above-defined alkyl group or an aryl group combined with a sulfur atom. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group or the like, but the disclosure is not limited thereto.

In the description, an oxy group may be the above-defined alkyl group or aryl group which is combined with an oxygen atom. The oxy group may include an alkoxy group and an aryl oxy group. The alkoxy group may be linear, branched, or cyclic. The number of carbon atoms in an alkoxy group is not specifically limited but may be, for example, 1 to 20 or 1 to 10. Examples of an oxy group may include methoxy, ethoxy, n-propoxy, isopropoxy, butoxy, pentyloxy, hexyloxy, octyloxy, nonyloxy, decyloxy, benzyloxy or the like. However, the disclosure is not limited thereto.

In the description, the number of carbon atoms in an amine group is not specifically limited, but may be 1 to 30. An amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group or the like, but the disclosure is not limited thereto.

In the description, a dithioic acid group may be a substituent having a structure of —S₂R. R may be a hydrogen atom, a substituted or unsubstituted alkyl group of 1 to 30 carbon atoms, a substituted or unsubstituted aryl group of 6 to 60 ring-forming carbon atoms, or a substituted or unsubstituted heteroaryl group of 2 to 60 ring-forming carbon atoms.

In the description, a phosphine group may include an alkyl phosphine group and an aryl phosphine group. The phosphine group may be an alkyl group or aryl group which is combined with a phosphor atom. Examples of the phosphine group may include a methylphosphine group, an ethylphosphine group, a propylphosphine group, a butylphosphine group, a pentylphosphine group, a hexylphosphine group, an octylphosphine group, a cyclopentylphosphine group, a cyclohexylphosphine group, a phenylphosphine group, a diphenylphosphine group, a triphenylphosphine group or the like, but the disclosure is not limited thereto.

In the description, a carboxyl group may be a substituent represented by Structure C1 below.

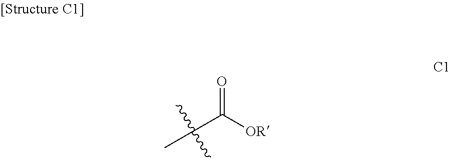

In Structure C1, R′ may be a hydrogen atom, a deuterium atom, a substituted or unsubstituted alkyl group of 1 to 30 carbon atoms, a substituted or unsubstituted aryl group of 6 to 60 ring-forming carbon atoms, or a substituted or unsubstituted heteroaryl group of 2 to 60 ring-forming carbon atoms.

In the description, (meth)acrylate may be acrylate or methacrylate.

In the description, symbols “ [symbol] ” and “ [symbol] ” may indicate positions to be connected.

In an embodiment, a ligand may include an ethylene glycol group. The ligand may increase the dispersibility of the quantum dot complex QD-C. In the description, the “ethylene glycol group” may be a residual group having —O(C₂H₄)—.

In an embodiment, the ligand may include a head part, a connection part connected with the heat part, and a tail part connected with the connection part. In an embodiment, the head part may be bonded to a surface of the shell SH.

The head part may be an electron donating head part. The head part may have a structure including an anion in a functional group. In an embodiment, the head part may include at least one of a hydroxyl group, a thiol group, a carboxylic acid group, a dithioic acid group, a phosphine group, a catechol group, and an amine group.

The ligand may include a tail part. The tail part may be connected with the head part. In an embodiment, the head part may be connected to a surface of the shell SH, and the tail part may be exposed to the outside of the quantum dot complex QD-C. In an embodiment, the tail part may include a hydroxyl group, a thiol group, a substituted or unsubstituted oxy group, a substituted or unsubstituted thio group, a substituted or unsubstituted (meth)acrylate group, or a substituted or unsubstituted alkyl group of 1 to 30 carbon atoms. For example, the tail part may include a substituted or unsubstituted methyl group or a substituted or unsubstituted acrylate group.

The ligand may include a connection part. The connection part of the ligand may be connected with the head part. The connection part may connect the head part and the tail part. For example, the ligand may include the head part, the connection part and the tail part, the connection part may be connected with the head part, and the tail part may be connected with the connection part. However, the disclosure is not limited thereto, and the tail part may be omitted in the ligand. In an embodiment, the connection part may include an ethylene glycol group. The connection part of the ligand may include an ethylene glycol group.

In an embodiment, the ligand may include a compound represented by Formula L below.

R₁—(OCH₂CH₂)ₘ—R₂ [Formula L]

In Formula L, R₁ may be a hydroxyl group, a thiol group, a carboxylic acid group, a dithioic acid group, a phosphine group, a catechol group or an amine group. For example, R₁ may be a thiol group or a carboxylic acid group.

In Formula L, R₂ may be a hydroxyl group, a thiol group, a substituted or unsubstituted oxy group, a substituted or unsubstituted thio group, a substituted or unsubstituted (meth)acrylate group or a substituted or unsubstituted alkyl group of 1 to 30 carbon atoms. For example, R₂ may be a substituted or unsubstituted methyl group, or a substituted or unsubstituted acrylate group.

In Formula L, “m” may be an integer of 1 to 20.

In Formula L, R₁ may correspond to the above-described head part, R₂ may correspond to the above-described tail part, and “—(OCH₂CH₂)ₘ—” may correspond to the above-described connection part.

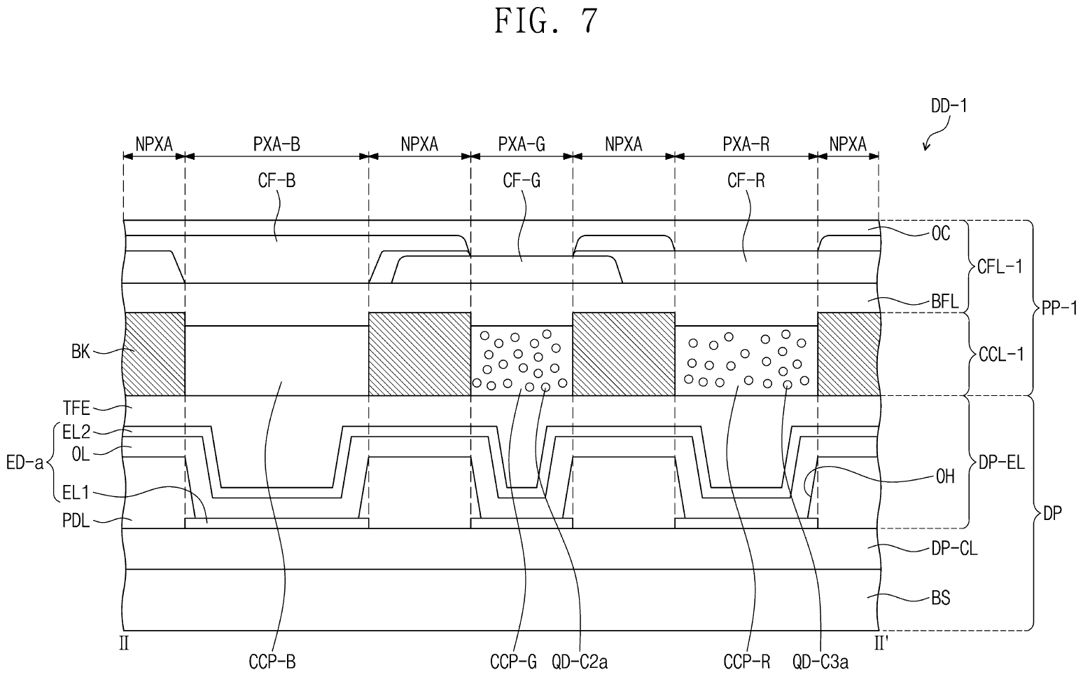

FIG. 7 is a schematic cross-sectional view of a display device DD-1 according to another embodiment of the disclosure. FIG. 7 shows a part corresponding to line II-II′ in FIG. 4. Hereinafter, in the explanation on the display device according to an embodiment of the disclosure referring to FIG. 7, the same configurations as those explained above will be provided with the same reference symbols, and detailed explanation thereof will be omitted.

The display device DD-1 of FIG. 7 may be different from the display device DD in FIG. 5A at least in that a base layer BL is omitted.

Referring to FIG. 7, the display device DD-1 may include a display panel DP and a light control layer PP-1 disposed on the display panel DP. The light control layer PP-1 may include a light conversion layer CCL-1 and a color filter layer CFL-1 disposed on the light conversion layer CCL-1.

The display device DD-1 shown in FIG. 7 may include the same display panel DP in FIG. 5A. The partition wall part BK of the light conversion layer CCL-1 may be disposed on an encapsulation layer TFE. The partition wall part BK may be disposed on (e.g., disposed directly on) the encapsulation layer TFE. Different from the display device DD shown in FIG. 5A, in the display device DD-1 of an embodiment, the configurations such as a partition wall part BK, a first light control part CCP-B, a second light control part CCP-G and a third light control part CCP-R may be disposed based on the top of the encapsulation layer TFE. In the opening parts of the partition wall part BK, the first light control part CCP-B, the second light control part CCP-G and the third light control part CCP-R may be disposed, respectively.

On the light conversion layer CCL-1, the color filter layer CFL-1 may be disposed. The color filter layer CFL-1 may include multiple filters CF-B, CF-G and CF-R, and an overcoat layer OC covering the multiple filters CF-B, CF-G and CF-R. The color filter layer CFL-1 may include a first filter CF-B overlapping a first light emitting area PXA-B, the second filter CF-G overlapping a second light emitting area PXA-G and the third filter CF-R overlapping a third light emitting area PXA-R in a plan view. The color filter layer CFL-1 included in the display device DD-1 of an embodiment, shown in FIG. 7 may not include a light blocking part BM, different from the color filter layer CFL included in the display device DD shown in FIG. 5A.

The first filter CF-B, the second filter CF-G and the third filter CF-R may define the first light emitting area PXA-B, the second light emitting area PXA-G, the third light emitting area PXA-R and a peripheral area NPXA. The area in which two or more filters among the first filter CF-B, the second filter CF-G and the third filter CF-R overlap each other in a plan view may be defined as a peripheral area NPXA. In each of the first light emitting area PXA-B, the second light emitting area PXA-G, and the third light emitting area PXA-R, only a corresponding filter among the first filter CF-B, the second filter CF-G and the third filter CF-R may be disposed. However, the disclosure is not limited thereto, and the display device DD-1 of an embodiment, shown in FIG. 7 may include a light blocking part BM (FIG. 5A) distinguishing the boundary between the filters CF-B, CF-G and CF-R. If the light blocking part BM (FIG. 5A) is further disposed, the peripheral area NPXA may be defined as an area in which the light blocking part BM (FIG. 5A) is disposed.

The overcoat layer OC may be an organic layer protecting multiple filters CF-R, CF-G and CF-B. The overcoat layer OC may include a photo-curable organic material or a thermo-curable organic material. However, the disclosure is not limited thereto, and the overcoat layer OC may include an inorganic material.

The color filter layer CFL-1 may further include a buffer layer BFL. The buffer layer BFL may be disposed between the light conversion layer CCL-1 and the multiple filters CF-B, CF-G and CF-R.

FIG. 8A is a schematic cross-sectional view of a display device DD-2 according to another embodiment of the disclosure. FIG. 8A shows a part corresponding to line II-II′ in FIG. 4. FIG. 8B is a schematic cross-sectional view of a light emitting element according to an embodiment of the disclosure.

Referring to FIG. 8A, a display device DD-2 may include a display panel DP-1 and a light control layer PP disposed on the display panel DP-1. The display panel DP-1 may include a base substrate BS, a circuit layer DP-CL disposed on the base substrate BS and a display element layer DP-EL-1 disposed on the circuit layer DP-CL.

The display element layer DP-EL-1 may include multiple light emitting elements ED-1, ED-2 and ED-3 emitting light in different wavelength ranges. For example, in an embodiment, the display device DD-2 may include a first light emitting element ED-1 emitting blue light, a second light emitting element ED-2 emitting green light and a third light emitting element ED-3 emitting red light. However, the disclosure is not limited thereto, and the first to third light emitting elements ED-1, ED-2 and ED-3 may emit light in a same wavelength range, or at least one may emit light in a different wavelength range.

For example, the blue light emitting area PXA-B, the green light emitting area PXA-G and the red light emitting area PXA-R of the display device DD-2 may correspond to the first light emitting element ED-1, the second light emitting element ED-2 and the third light emitting element ED-3, respectively.

The display device DD-2 of an embodiment may include multiple light emitting elements ED-1, ED-2 and ED-3, and at least one of the light emitting elements ED-1, ED-2 and ED-3 may include emission layers EL-B, EL-G and EL-R including quantum dot complexes QD-C1, QD-C2 and QD-C3 according to an embodiment.

The display device DD-2 of an embodiment may include a display panel DP-1 including multiple light emitting elements ED-1, ED-2 and ED-3, and a light control layer PP disposed on the display panel DP-1. In another embodiment, the light control layer PP may be omitted in the display device DD-2 of an embodiment.

The display panel DP may include a base substrate BS, a circuit layer DP-CL provided on the base substrate BS and a display element layer DP-EL-1, and the display element layer DP-EL-1 may include a pixel definition layer PDL, light emitting elements ED-1, ED-2 and ED-3 disposed in the pixel definition layer PDL, and an encapsulation layer TFE disposed on the light emitting elements ED-1, ED-2 and ED-3.

The first emission layer EL-B of the first light emitting element ED-1 may include a fourth quantum dot complex QD-C1. The fourth quantum dot complex QD-C1 may emit blue light that is first light.

The second emission layer EL-G of the second light emitting element ED-2 and the third emission layer EL-R of the third light emitting element ED-3 may include a fifth quantum dot complex QD-C2 and a sixth quantum dot complex QD-C3, respectively. The fifth quantum dot complex QD-C2 may emit green light that is second light and the sixth quantum dot complex QD-C3 may emit red light that is third light.

At least one of the fourth to sixth quantum dot complexes QD-C1, QD-C2 and QD-C3 may be the above-described quantum dot complex according to an embodiment. In an embodiment, the fifth quantum dot complex QD-C2 may be the above-described quantum dot complex according to an embodiment. However, the disclosure is not limited thereto, and each of the fourth to sixth quantum dot complexes QD-C1, QD-C2 and QD-C3 may be the above-described quantum dot complex according to an embodiment.

In an embodiment, the fourth to sixth quantum dot complexes QD-C1, QD-C2 and QD-C3 included in the light emitting elements ED-1, ED-2 and ED-3 may be formed from different core materials. In another embodiment, the fourth to sixth quantum dot complexes QD-C1, QD-C2 and QD-C3 may be formed from a same core material, or two quantum dots selected from the fourth to sixth quantum dot complexes QD-C1, QD-C2 and QD-C3 may be formed from a same core material, and the remainder may be formed from a different core material.

In an embodiment, the fourth to sixth quantum dot complexes QD-C1, QD-C2 and QD-C3 may have different diameters. For example, the fourth quantum dot complex QD-C1 in the first light emitting element ED-1 which emits light in shorter wavelength range may have a shorter average diameter compared to the fifth quantum dot complex QD-C2 of the second light emitting element ED-2 and the sixth quantum dot complex QD-C3 of the third light emitting element ED-3, which emit light in higher wavelength ranges.

The relation between the average diameter of the fourth to sixth quantum dot complexes QD-C1, QD-C2 and QD-C3 is not particularly limited. For example, the sizes of the fourth to sixth quantum dot complexes QD-C1, QD-C2 and QD-C3 are similar in FIG. 8A, but the disclosure is not limited thereto, and in another embodiment, the sizes of the fourth to sixth quantum dot complexes QD-C1, QD-C2 and QD-C3 included in the light emitting elements ED-1, ED-2 and ED-3 may be different from each other. In another embodiment, the average diameter of two quantum dots selected from the fourth to sixth quantum dot complexes QD-C1, QD-C2 and QD-C3 may be similar, and the remainder may have a different average diameter.

The pixel definition layer PDL may be formed from an inorganic material. For example, the pixel definition layer PDL may include silicon nitride (SiNₓ), silicon oxide (SiOₓ), silicon oxynitride (SiOₓN_{y}) or the like. The pixel definition layer PDL may define the light emitting areas PXA-B, PXA-G and PXA-R. By the pixel definition layer PDL, the light emitting areas PXA-B, PXA-G and PXA-R and the peripheral area NPXA may be divided.

Each of the light emitting elements ED-1, ED-2 and ED-3 may include a first electrode EL1, a hole transport region HTR, emission layers EL-B, EL-G and EL-R, an electron transport region ETR and a second electrode EL2. The same contents explained in FIG. 8B, which will be explained below may be applied to the first electrode EL1, the hole transport region HTR, the electron transport region ETR and the second electrode EL2 except that the quantum dot complexes QD1, QD2 and QD3 included in the emission layers EL-B, EL-G and EL-R in the light emitting elements ED-1, ED-2 and ED-3 included in the display device DD of an embodiment are different from each other. Although not shown, each of the light emitting elements ED-1, ED-2 and ED-3 may further include a capping layer between the second electrode EL2 and the encapsulation layer TFE.

The encapsulation layer TFE may cover the light emitting elements ED-1, ED-2 and ED-3. The encapsulation layer TFE may protect the light emitting elements ED-1, ED-2 and ED-3. The encapsulation layer TFE may cover the top of the second electrode EL2 disposed in the opening part OH and fill the opening part OH.

Referring to FIG. 8 or the like, the hole transport region HTR and the electron transport region ETR may be provided as common layers, covering the pixel definition layer PDL, but the disclosure is not limited thereto. In an embodiment, the hole transport region HTR and the electron transport region ETR may be disposed in the opening part OH defined in the pixel definition layer PDL.

For example, if the hole transport region HTR and the electron transport region ETR as well as the emission layers EL-B, EL-G and EL-R are provided by an inkjet printing method, the hole transport region HTR, the emission layers EL-B, EL-G and EL-R, and the electron transport region ETR may be provided corresponding to the opening part OH defined in the pixel definition layer PDL. However, the disclosure is not limited thereto, and the hole transport region HTR and the electron transport region ETR may not be patterned and may be provided as common layers, while covering the pixel definition layer PDL, irrespective of the providing method of each functional layer.

In the display device DD-2 of an embodiment, shown in FIG. 8A, the thicknesses of the emission layers EL-B, EL-G and EL-R of the first to third light emitting elements ED-1, ED-2 and ED-3 are shown similar, but the disclosure is not limited thereto. For example, in another embodiment, the thicknesses of the emission layers EL-B, EL-G and EL-R of the first to third light emitting elements ED-1, ED-2 and ED-3 may be different from each other.

The display device DD-2 of an embodiment may further include a light control layer PP. The light control layer PP may block external light provided to the display panel DP from the outside of the display device DD-2. The light control layer PP may block a portion of the external light. The light control layer PP may have anti-reflection function to minimize the reflection by the external light. The light control layer PP may include a color filter layer CFL and a base layer BL disposed on the display element layer DP-EL-1. The same contents explained in FIG. 5A may be applied to the color filter layer CFL and the base layer BL.

FIG. 8B is a schematic diagram showing a light emitting element ED according to an embodiment, and referring to FIG. 8B, the light emitting element ED according to an embodiment may include a first electrode EL1, a second electrode EL2 oppositely disposed to the first electrode EL1, and multiple functional layers including an emission layer EML disposed between the first electrode EL1 and the second electrode EL2. The light emitting element ED shown in FIG. 8B may correspond to at least one of the light emitting elements ED-1, ED-2 and ED-3 shown in FIG. 8A.

The functional layers may include a hole transport region HTR disposed between the first electrode EL1 and the emission layer EML, and an electron transport region ETR disposed between the emission layer EML and the second electrode EL2. Although not shown in the drawing, in an embodiment, a capping layer may be further disposed on the second electrode EL2.

The hole transport region HTR and the electron transport region ETR may each include multiple sub-functional layers. For example, the hole transport region HTR may include a hole injection layer HIL and a hole transport layer HTL as sub-functional layers, and the electron transport region ETR may include an electron injection layer EIL and an electron transport layer ETL as sub-functional layers. However, the disclosure is not limited thereto, and the hole transport region HTR may further include an electron blocking layer (not shown) as sub-functional layer, and the electron transport region ETR may further include a hole blocking layer (not shown) as sub-functional layer.

In the light emitting element ED according to an embodiment, the first electrode EL1 may have conductivity. The first electrode EL1 may be formed using a metal alloy or a conductive compound. The first electrode EL1 may be an anode. The first electrode EL1 may be a pixel electrode.

In the light emitting element ED according to an embodiment, the first electrode EL1 may be reflective electrode. However, the disclosure is not limited thereto. For example, the first electrode EL1 may be a transmissive electrode or a transflective electrode. If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). In an embodiment, the first electrode EL1 may have multilayer structure including a reflective layer or a transflective layer formed from the above-described materials, and a transmissive conductive layer formed from indium tin oxide (ITO), indium zinc oxide (IZO), zinc oxide (ZnO), indium tin zinc oxide (ITZO) or the like. For example, the first electrode EL1 may have multiple metal layers or a stacked structure of metal layers of ITO/Ag/ITO.

The hole transport region HTR may be provided on the first electrode EL1. The hole transport region HTR may include a hole injection layer HIL, a hole transport layer HTL, and the like. The hole transport region HTR may further include at least one of a hole buffer layer (not shown) and an electron blocking layer (not shown) in addition to the hole injection layer HIL and the hole transport layer HTL. The hole buffer layer (not shown) may compensate a resonance distance according to the wavelength of light emitted from the emission layer EML and may increase light emission efficiency. As a material included in the hole buffer layer (not shown), materials included in the hole transport region HTR may be used. The electron blocking layer (not shown) may be a layer that blocks electron injection from the electron transport region ETR to the hole transport region HTR.

The hole transport region HTR may have a layer composed of a material, a layer composed of different materials, or a structure having layers composed of different materials. For example, the hole transport region HTR may have a structure of a layer formed using different materials, or a structure stacked from the first electrode EL1 of hole injection layer HIL/hole transport layer HTL, hole injection layer HIL/hole transport layer HTL/hole buffer layer (not shown), hole injection layer HIL/hole buffer layer (not shown), hole transport layer HTL/hole buffer layer (not shown), or hole injection layer HIL/hole transport layer HTL/electron blocking layer (not shown), but the disclosure is not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole injection layer HIL may include, for example, a phthalocyanine compound such as copper phthalocyanine, N,N′-diphenyl-N,N′-bis-[4-(phenyl-m-tolyl-amino)-phenyl]-biphenyl-4,4′-diamine (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris {N,-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPD), triphenylamine-containing polyetherketone (TPAPEK), 4-isopropyl-4′-methyldiphenyliodonium [tetrakis(pentafluorophenyl) borate], dipyrazino[2,3-f: 2′,3′-h]quinoxaline-2,3,6,7,10,11-hexacarbonitrile (HAT-CN) and the like.

The hole transport layer HTL may include a material used in this technical field. For example, the hole transport layer HTL may include a carbazole derivative such as N-phenyl carbazole and polyvinyl carbazole, fluorene-based derivatives, N,N′-bis(3-methylphenyl)-N,N′-diphenyl-[1,1-biphenyl]-4,4′-diamine (TPD), triphenylamine-based derivatives such as 4,4′,4″-tris(N-carbazolyl)triphenylamine (TCTA), N,N′-di(1-naphthalene-1-yl)-N,N′-diphenyl-benzidine (NPD), 4,4′-cyclohexylidene bis[N,N-bis(4-methylphenyl)benzeneamine] (TAPC), 4,4′-bis[N,N′-(3-tolyl)amino]-3,3′-dimethylbiphenyl (HMTPD), 1,3-bis(N-carbazolyl)benzene (mCP) and the like.

A thickness of the hole transport region HTR may be in a range of about 5 nm to about 1,500 nm. For example, the thickness of the hole transport region HTR may be in a range of about 10 nm to about 500 nm. A thickness of the hole injection layer HIL may be, for example, in a range of about 3 nm to about 100 nm, and the thickness of the hole transport layer HTL may be in a range of about 3 nm to about 100 nm. For example, the thickness of the electron blocking layer (not shown) may be in a range of about 1 nm to about 100 nm. If the thicknesses of the hole transport region HTR, the hole injection layer HIL, the hole transport layer HTL and the electron blocking layer (not shown) satisfy the above-described ranges, satisfactory hole transport properties may be achieved without substantial increase of a driving voltage.

The emission layer EML may be provided on the hole transport region HTR. The emission layer EML may include a quantum dot complex QD-C. The quantum dot complex QD-C may include a quantum dot QD (FIG. 5A), a shell SH (FIG. 5B) and nanoparticles NP (FIG. 5B). The same contents explained in FIG. 5B may be applied to the quantum dot complex QD-C included in the emission layer EML of the light emitting element ED, shown in FIG. 8B.

The emission layer EML may include multiple quantum dot complex QD-C. The quantum dot complex QD-C included in the emission layer EML may be stacked each other to form a layer. In FIG. 8B, quantum dot complex QD-C having a circular cross-section and arranged to roughly two layers is shown as an embodiment, but the disclosure is not limited thereto. For example, the arrangement of the quantum dot complex QD-C may vary depending on the thickness of the emission layer EML, the shape of the quantum dot complex QD-C included in the emission layer EML, the average diameter of the quantum dot complex QD-C, the type of a ligand bonded to the surface of the quantum dot complex QD-C or the like. For example, the quantum dot complex QD-C in the emission layer EML may be arranged next to each other to form one layer, or to form multiple layers such as two or three layers.

A maximum emission wavelength range of the emission layer EML may be in a range of about 510 nm to about 550 nm. The emission layer EML may emit green light in a wavelength in a range of about 510 nm to about 550 nm. However, the disclosure is not limited thereto, and the emission layer EML may emit blue light or red light. The emission center wavelength of the emission layer EML may be in a range of about 430 nm to about 490 nm. In another embodiment, the emission center wavelength of the emission layer EML may be in a range of about 590 nm to about 680 nm.

In the light emitting element ED of an embodiment, the emission layer EML may include a host and a dopant. In an embodiment, the emission layer EML may include the quantum dot QD as a dopant. In an embodiment, the emission layer EML may further include a host.

In the light emitting element ED of an embodiment, the emission layer EML may emit fluorescence light. For example, the quantum dot complex QD-C may be used as a fluorescence dopant material.

In the light emitting element ED of an embodiment, the electron transport region ETR may be provided on the emission layer EML. The electron transport region ETR may include at least one of a hole blocking layer (not shown), an electron transport layer ETL, and an electron injection layer EIL, but the disclosure is not limited thereto.

The electron transport region ETR may have a layer formed using a material, a layer formed using materials or a structure having layers formed using multiple materials.

For example, the electron transport region ETR may have a single layer structure of an electron injection layer EIL or an electron transport layer ETL, or a single layer structure formed using an electron injection material and an electron transport material. The electron transport region ETR may have a single layer structure formed using different materials, or a structure stacked from the emission layer EML of electron transport layer ETL/electron injection layer EIL, or hole blocking layer (not shown)/electron transport layer ETL/electron injection layer EIL, but the disclosure is not limited thereto. A thickness of the electron transport region ETR may be, for example, in a range of about 20 nm to about 150 nm.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

If the electron transport region ETR includes an electron transport layer ETL, the electron transport region ETR may include an anthracene-based compound. However, the disclosure is not limited thereto. The electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl) biphenyl-3-yl)-1,3,5-triazine, bis[2-(diphenylphosphino)phenyl] ether oxide (DPEPO), 2-(4-(N-phenylbenzoimidazolyl-1-yl)phenyl)-9,10-dinaphthylanthracene, 1,3,5-tri (1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl) anthracene (ADN), and a mixture thereof. A thickness of the electron transport layer ETL may be in a range of about 10 nm to about 100 nm. For example, the thickness of the electron transport layer ETL may be in a range of about 15 nm to about 50 nm. If the thickness of the electron transport layer ETL satisfies the above-described range, satisfactory electron transport properties may be obtained without substantial increase of a driving voltage.

If the electron transport region ETR includes an electron injection layer EIL, the electron transport region ETR may include a metal halide such as LiF, NaCl, CsF, RbCl, and RbI, a lanthanoide metal such as Yb, a metal oxide such as Li₂O and BaO, or lithium quinolate (LiQ), but the disclosure is not limited thereto. The electron injection layer EIL may be formed using a mixture material of an electron transport material and an insulating organo metal salt. For example, the organo metal salt may include a metal acetate, a metal benzoate, a metal acetoacetate, a metal acetylacetonate, or a metal stearate. A thickness of the electron injection layer EIL may be in a range of about 0.1 nm to about 10 nm. For example, the thickness of the electron injection layer EIL may be in a range of about 0.3 nm to about 9 nm. If the thickness of the electron injection layer EIL satisfies the above-described range, satisfactory electron injection properties may be obtained without substantial increase of a driving voltage.

The electron transport region ETR may include a hole blocking layer (not shown) as described above. The hole blocking layer (not shown) may include, for example, at least one of 2,9-dimethyl-4,7-diphenyl-1,10-phenanthroline (BCP), and 4,7-diphenyl-1,10-phenanthroline (Bphen). However, the disclosure is not limited thereto.

The second electrode EL2 may be provided on the electron transport region ETR. The second electrode EL2 may be a common electrode or a negative electrode. The second electrode EL2 may be a transmissive electrode, a transflective electrode or a reflective electrode. If the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO) or the like.

If the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, a compounds thereof (for example, AgYb, or AgMg and AgYb according to the content), or a mixture thereof (for example, a mixture of Ag and Mg). In another embodiment, the second electrode EL2 may have a multilayered structure including a reflective layer or a transflective layer formed using the above-described materials and a transparent conductive layer formed using ITO, IZO, ZnO, ITZO or the like.

Though not shown, the second electrode EL2 may be connected with an auxiliary electrode. If the second electrode EL2 is connected with the auxiliary electrode, a resistance of the second electrode EL2 may be reduced.

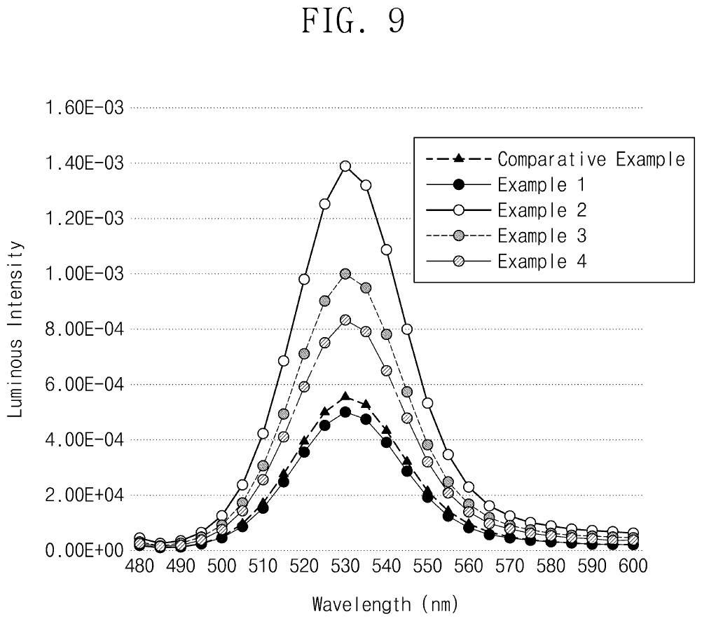

FIG. 9 is a graph showing luminous intensity in accordance with the wavelength of the Examples and the Comparative Example.

The quantum dot complexes of Example 1 to Example 4, used in FIG. 9 have the structure of the quantum dot complex QD-C shown in FIG. 5B, and include a quantum dot QD including a core CO, a first middle shell MSH1, and a second middle shell MSH2, a shell SH and nanoparticles NP. The quantum dot QD has the core-middle shell structure of InP/ZnSe/ZnS, the shell SH includes silicon oxide (SiO₂) and the nanoparticle NP includes silver. The quantum dot complexes of Example 1 to Example 4 have a same configuration except for the thickness of the shell SH. Example 1 corresponds to a case where the thickness of the shell SH is about 10 nm, Example 2 corresponds to a case where the thickness of the shell SH is about 20 nm, Example 3 corresponds to a case where the thickness of the shell SH is about 30 nm, and Example 4 corresponds to a case where the thickness of the shell SH is about 40 nm. The quantum dot complex of the Comparative Example, used in FIG. 9 has a same configuration as the quantum dot complexes of the Examples except for the shell SH and the nanoparticles NP are not included compared to the quantum dot complexes of the Examples. For example, the quantum dot complex of the Comparative Example may correspond to a quantum dot QD having the core-middle shell structure of InP/ZnSe/ZnS.

In the quantum dot complex QD-C of an embodiment, a luminous intensity of the quantum dot QD may vary depending on a thickness of the shell SH. Referring to FIG. 9, it can be confirmed that Example 1 in which the thickness of the shell SH is about 10 nm showed the similar degree of luminous intensity as the Comparative Example. It can be confirmed that Example 2 to Example 4, in which the thicknesses of the shell SH are respectively about 20 nm, about 30 nm and about 40 nm, showed higher luminous intensity than the Comparative Example. The quantum dot complexes QD-C of the Examples include the shell SH surrounding the quantum dot QD, and the nanoparticles NP disposed on the surface of the shell SH, and may show improved luminous intensity due to surface plasmon resonance phenomenon by the nanoparticles NP.

Referring to FIG. 9, it can be confirmed that if the thickness of the shell SH increases, the luminous intensity gradually increases and gradually decreases. For example, Example 2 in which the thickness of the shell SH is about 20 nm showed the maximum luminous intensity, and Examples 3 and 4 in which the thicknesses of the shell SH are respectively about 30 nm and about 40 nm showed decreasing tendency of the luminous intensity again. This is thought to be a result obtained because, as the thickness of the shell SH increases, the distance between the quantum dot QD and the nanoparticle NP increases, and a quenching phenomenon by the nanoparticle NP decreases, but as the gap between the quantum dot QD and the nanoparticle NP increases, a surface plasmon resonance phenomenon significantly decreases. Accordingly, from the result of FIG. 9, it can be found that the luminous efficiency of the quantum dot QD may be improved by controlling the thickness of the shell SH to in a range of about 10 nm to about 50 nm.

The surface plasmon resonance effect may be influenced by the gap between the quantum dot QD and the nanoparticle NP and the overlap degree of spectrum. The transfer of light energy from the quantum dot QD to the nanoparticle NP may depend on the gap between the quantum dot QD and the nanoparticle NP. If the gap between the quantum dot QD and the nanoparticle NP increases, the surface plasmon resonance phenomenon significantly decreases, and in order to obtain target light emission efficiency, it may be important to control the gap between the quantum dot QD and the nanoparticle NP.

If the nanoparticle NP contacts the surface of the quantum dot QD, or the distance between the nanoparticle NP and the quantum dot QD is too close, a quenching phenomenon may occur due to the nanoparticle NP, which may reduce luminous efficiency. For example, a direct energy transfer may occur from the nanoparticle NP to the quantum dot QD, and the quenching phenomenon may be induced. In the disclosure, the distance between the quantum dot QD and the nanoparticle NP may be controlled to a certain range by controlling the thickness of the shell SH, and accordingly, the surface plasmon resonance phenomenon may increase, and the light emission efficiency of the quantum dot QD may be improved. For example, by controlling the shell SH to have a certain thickness, the quenching phenomenon by the nanoparticle NP may be prevented, and accordingly, the surface plasmon resonance phenomenon may be optimized, and a quantum dot QD having high light emission efficiency may be realized.

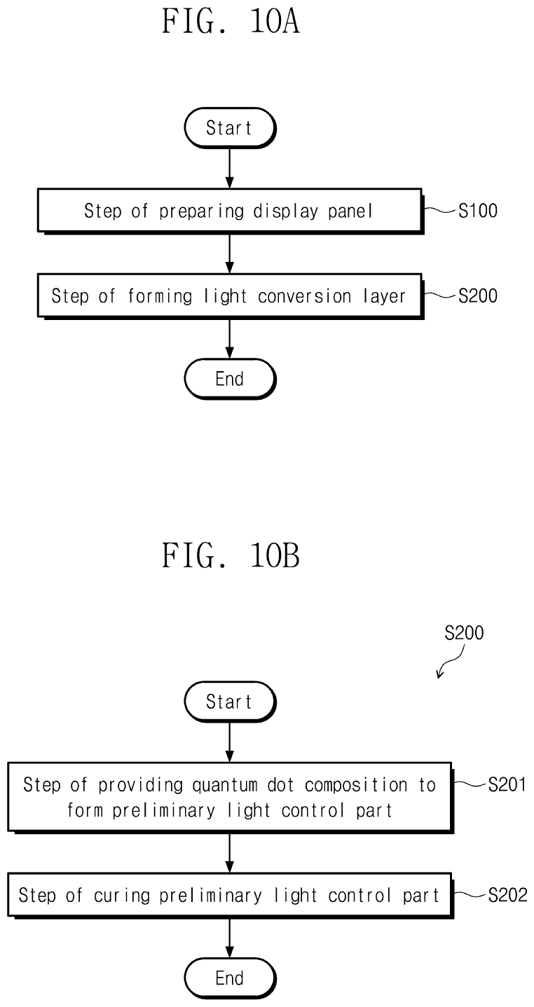

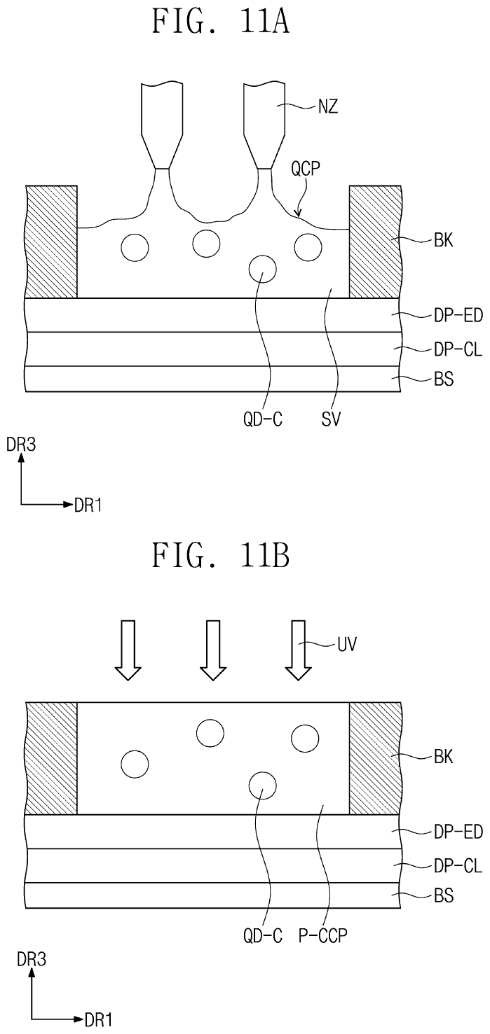

FIG. 10A is a flowchart showing a method for manufacturing a display device according to an embodiment of the disclosure. FIG. 10B is a flowchart detailing a step of forming a light control layer according to an embodiment of the disclosure.

Referring to FIG. 10A, a method for manufacturing a display device according to an embodiment may include a step of preparing a display panel (S100), and a step of forming a light conversion layer (S200).

Referring to FIG. 10B, the step of forming a light conversion layer according to an embodiment may include a step of providing a quantum dot composition to form a preliminary light control part (S201), and a step of curing the preliminary light control part (S202). In the display devices DD and DD-1 of embodiments, described in FIG. 1 to FIG. 5B and FIG. 7, at least one of the light control parts CCP-B, CCP-G and CCP-R included in the light conversion layer CCL may be formed through a step of forming a light conversion layer, which will be explained below.

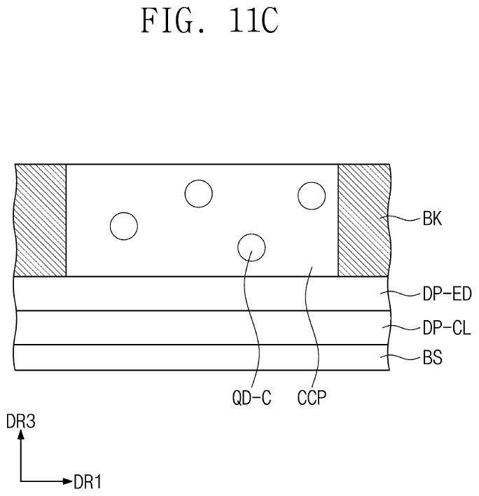

FIG. 11A to 11C are schematic cross-sectional views showing some steps in the method for manufacturing a display device according to an embodiment of the disclosure. In FIG. 11A to FIG. 11C, a step of forming a light conversion layer in the method for manufacturing of a display device according to an embodiment of the disclosure is shown in order. Hereinafter, in explaining the method for manufacturing a display device according to an embodiment referring to FIG. 11A to FIG. 11C, the same reference symbols are provided for the same configurations as the configurations explained above, and detailed description thereof will be omitted.

The method for manufacturing a display device according to an embodiment of the disclosure may include a step of preparing a display panel and a step of forming a light conversion layer on the display panel.

Referring to FIG. 11A, the step of forming a light conversion layer in the method for manufacturing a display device according to an embodiment may include a step of providing a quantum dot composition QCP on a base surface to form a light control part CCP (FIG. 11C). A method for providing the quantum dot composition QCP on the base surface is not specifically limited, and methods such as a spin coating method, a case method, a Langmuir-Blodgett (LB) method, an inkjet printing method, a laser printing method, and a laser induced thermal imaging (LITI) method may be used. FIG. 11A illustrates that the quantum dot composition QCP is applied onto the base surface via nozzles NZ, but the disclosure is not limited thereto, and the quantum dot composition QCP may be provided onto the base surface by various methods.

In FIG. 11A to FIG. 11C, the configuration providing the base surface for the application of the quantum dot composition QCP is shown as a display element layer DP-ED, but the disclosure is not limited thereto. The quantum dot composition QCP may be applied on the base surface provided by the functional layers included in the light control layer PP (FIG. 5A and FIG. 7), for example, the base layer BL (FIG. 5A and FIG. 7) or the color filter layer CFL (FIG. 5A and FIG. 7). The method for manufacturing a display device of an embodiment may further include a step of patterning multiple partition wall parts BK on the base surface prior to the step of applying the quantum dot composition QCP. For example, as in FIG. 11A, if the configuration providing the base surface is the display element layer DP-ED, a step of patterning multiple partition wall parts BK on the display element layer DP-ED may be further included prior to the step of applying the quantum dot composition QCP.

The quantum dot composition QCP may be provided between multiple partition wall parts BK. The quantum dot composition QCP may include a base resin SV and a quantum dot complex QD-C dispersed in the base resin SV. The same explanation on the quantum dot complex referring to FIG. 5B or the like may be applied to the quantum dot complex QD-C included in the quantum dot composition QCP.

The base resin SV may include an acrylic resin, a methacrylic resin, a urethane-based resin, a fluorine-based resin, an epoxy-based resin, a vinyl-based resin, a polyester-based resin, a polyamide-based resin, a polyimide-based resin, a cellulose-based resin, a perylene-based resin, a silicon-based resin, or a combination thereof.

The quantum dot composition QCP of an embodiment may further include an additional additive. The additive may be selected from a common additive in this technical field for controlling the physical properties required for the quantum dot composition QCP. For example, a dispersant, a light stabilizer, a crosslinking agent, an antioxidant, a chain transfer agent, a photosensitizer, a polymerization inhibitor, a leveling agent, a surfactant, an adhesion imparting agent, a plasticizer, a ultraviolet absorber, a storage stabilizer, an antistatic agent, an inorganic filler, a pigment and a dye may be used, but the disclosure is not limited thereto. The additive may be used alone or in combination of two or more thereof.

The quantum dot composition QCP of an embodiment may further include an initiator. In the description, the initiator may be a compound capable of initiating a radical polymerization by heat or light. The initiator may be a thermal initiator or a photo initiator.

The quantum dot composition QCP of an embodiment may include a thermal initiator. Examples of the thermal initiator may include azobisisobutyronitrile, but the disclosure is not limited thereto.

The quantum dot composition QCP of an embodiment may include a photo initiator. The photo initiator may include triazine compounds, acetophenone compounds, benzophenone compounds, thioxanthone compounds, benzoin compounds, oxime ester compounds, aminoketone compounds, phosphine or phosphine oxide compounds, carbazole-based compounds, diketone compounds, sulfonium borate compounds, diazo-based compounds, biimidazole-based compounds, or a combination thereof, but the disclosure is not limited thereto. If the quantum dot composition QCP includes multiple photo initiators, different photo initiators may be activated by ultraviolet light having different center wavelengths.

For example, the photo initiator may include at least one of 2,2-dimethoxy-1,2-diphenylethan-1-one, 1-hydroxy-cyclohexyl-phenyl-ketone, 2-hydroxy-2-methyl-1-phenyl-1-propanone, 2-hydroxy-1-[4-(2-hydroxyethoxy)phenyl]-2-methyl-1-propanone, and 2-hydroxy-1-{4-[4-(2-hydroxy-2-methyl-propionyl)-benzyl]-phenyl}-2-methylpropan-1-one.

For example, the photo initiator may include at least one of 2-methyl-1 [4-(methylthio)phenyl]-2-morpholinopropan-1-one), 2-benzyl-2-dimethylamino-1-(4-morpholinophenyl)-butanone-1,2-dimethylamino-2-(4-methyl-benzyl)-1-(4-morpholin-4-yl-phenyl)-butan-1-one, 2,4,6-trimethylbenzoyl-diphenylphosphine oxide, 2,4,6-trimethylbenzoyl-diphenyl phosphinate, bis(2,4,6-trimethylbenzoyl)-phenylphosphineoxide, [1-(4-phenylsulfanylbenzoyl)heptylideneamino]benzoate, [1-[9-ethyl-6-(2-methylbenzoyl) carbazol-3-yl]ethylideneamino] acetate, and bis(2,4-cyclopentadienyl)bis[2,6-difluoro-3-(1-pyrryl)phenyl] titanium (IV).

The quantum dot composition QCP may further include a solvent. In the step of forming the light control part CCP, the solvent may be removed. However, the disclosure is not limited thereto, and a portion of the solvent may remain on the light control part CCP.

The solvent may be an organic solvent or an inorganic solvent such as water. Examples of the organic solvent may include, for example, hexane, toluene, chloroform, dimethyl sulfoxide, octane, xylene, hexadecane, cyclohexylbenzene, triethylene glycol monobutyl ether, dimethyl formamide, decane, dodecane, hexadecene, cyclohexylbenzene, tetrahydronaphthalene, ethylnaphthalene, ethylbiphenyl, isopropylnaphthalene, diisopropylnaphthalene, diisopropylbiphenyl, xylene, isopropylbenzene, pentylbenznene, diisopropylbenzene, decahydronaphthalene, phenylnaphthalene, cyclohexyldecahydronaphthalene, decylbenzene, dodecylbenzene, octylbenzene, cyclohexane, cyclopentane, cycloheptane, methanol, ethanol, propanol, isopropanol, ethylene glycol, propylene glycol, or diethylene glycol, but the disclosure is not limited thereto.

The quantum dot composition QCP may further include a scatterer. The scatterer may be inorganic particles. For example, the scatter may include at least one of TiO₂, ZnO, Al₂O₃, SiO₂, and hollow silica. The scatterer may include at least one of TiO₂, ZnO, Al₂O₃, SiO₂, hollow silica, and a mixture of two or more materials selected from TiO₂, ZnO, Al₂O₃, SiO₂, and hollow silica.

In an embodiment, a content of the quantum dot complex QD-C may be less than or equal to about 45 wt % on the basis of about 100 wt % of the total content of the quantum dot composition QCP. For example, the content of the quantum dot complex QD-C may be in a range of about 10 wt % to about 40 wt %. If the content of the quantum dot complex QD-C included in the quantum dot composition QCP satisfies the above-described range, the solution processability of the composition may be improved, and the luminous efficiency of a light control part CCP which will be formed later, may be sufficiently maintained.

The content of the quantum dot complex QD-C in the quantum dot composition QCP may influence the solution processability of the composition and the luminous properties of a thin film formed from the composition. In order to improve the solution processability, the composition may be required to have low viscosity. The quantum dot content may significantly influence the viscosity of the quantum dot composition, and the low viscosity properties of the quantum dot composition may be achieved by reducing the quantum dot content. However, the decrease of the quantum dot content in the quantum dot composition may be accompanied by the decrease of external quantum efficiency, and accordingly, the improvement of quantum dot materials that simultaneously satisfy the low viscosity properties of the composition and the external quantum efficiency may be required.

According to the method for manufacturing a display device according to an embodiment of the disclosure, the quantum dot composition QCP may include a quantum dot complex QD-C including a quantum dot QD, a shell SH surrounding the quantum dot QD, and nanoparticles NP bonded to the surface of the shell SH, and a quantum dot composition QCP simultaneously satisfying low viscosity properties and excellent external quantum efficiency properties may be accomplished. In the quantum dot composition QCP of the disclosure, though a small amount of the quantum dot complex QD-C is contained in the quantum dot composition QCP, the external quantum efficiency of the quantum dot composition may be maintained high, and the luminous efficiency of the light control part CCP formed therefrom may be improved. Since the content of the quantum dot complex QD-C may be reduced, the viscosity of the quantum dot composition QCP may be maintained low, and solution processability may be improved.

In an embodiment, a viscosity of the quantum dot composition QCP may be less than or equal to about 25 cps. For example, the viscosity of the quantum dot composition QCP may be in a range of about 1 cps to about 20 cps. If the viscosity of the quantum dot composition QCP satisfies the above-described range, excellent solution processability may be shown.

Referring to FIG. 11A and FIG. 11B, the quantum dot composition QCP may form a preliminary light control part P-CCP. The preliminary light control part P-CCP formed from the quantum dot composition QCP may include a base resin SV and a quantum dot complex QD-C dispersed in the base resin SV.

FIG. 11B is a schematic diagram showing a step of curing the preliminary light control part P-CCP (S202) in the method for manufacturing a display device according to an embodiment. The step of curing the preliminary light control part P-CCP according to an embodiment may include a step of providing heat or light to the preliminary light control part P-CCP. FIG. 11B illustrates that light (UV) is provided to the preliminary light control part P-CCP, but the disclosure is not limited thereto.

Referring to FIG. 11B and FIG. 11C, a light control part CCP may be formed by curing the preliminary light control part P-CCP. The light control part CCP may include the quantum dot complex QD-C. The quantum dot complex QD-C may be included and present in a finally formed light control part CCP. A display device DD including the light control part CCP formed from the quantum dot composition QCP of an embodiment may have improved luminous properties.

Although not shown, the method for manufacturing a display device according to an embodiment may further include a step of baking the preliminary light control part P-CCP after the step of curing the preliminary light control part P-CCP. The step of baking the preliminary light control part P-CCP may be a step of providing heat of a temperature higher than or equal to about 50° C. The baking may be for removing the solvent included in the preliminary light control part P-CCP. For example, the step of baking the preliminary light control part P-CCP may be a step of providing heat of a temperature higher than or equal to about 100° C. to remove the solvent contained in the preliminary light control part P-CCP.

Although not shown, at least one of the light emitting elements ED-1, ED-2 and ED-3 shown in FIG. 8A may be formed by a same method as the method of forming the light conversion layer. The light emitting element ED shown in FIG. 8B may be formed by a same method as the method of forming the light conversion layer. For example, the method for manufacturing the light emitting element ED shown in FIG. 8B may include a step of forming a hole transport region HTR on a first electrode EL1, a step of forming an emission layer EML on the hole transport region HTR, a step of forming an electron transport region ETR on the emission layer EML, and a step of forming a second electrode EL2 on the electron transport region ETR, and the step of forming the emission layer EML may include a step of providing the above-described quantum dot composition QCP to form a preliminary emission layer, and a step of curing the preliminary emission layer. Here, with respect to the step of forming the preliminary emission layer and the step of curing the preliminary emission layer, the same contents explained in the step of forming the preliminary light control part and the step of curing the preliminary light control part in FIG. 11A to FIG. 11C may be applied.

Hereinafter, referring to Examples and Comparative Examples, the quantum dot according to an embodiment of the disclosure will be explained in particular. The examples below are illustrations to assist the understanding of the disclosure, and the scope of the disclosure is not limited thereto.

### EXAMPLES

### 1. Preparation of Quantum Dot Complex

### 1) Example

### Step 1: Preparation of InP Core

2.8 mmol of indium iodide, 10 ml of oleylamine, 5 g of sodium oleate and 10 ml of trioctylphosphine (TOP) were put in a three neck flask and mixed, and oxygen and moisture were removed in a vacuum state at about 120° C. for about 60 minutes. The temperature was raised to about 180° C., and N₂ purging was performed. A mixture solution of 5 ml of TOP and 1.4 ml of (TMS)₃P, prepared in advance was rapidly injected thereto, and the temperature was raised to about 220° C., followed by reacting for about 10 minutes to synthesize an InP core. 50 ml of ethanol was added to the reaction product to precipitate, centrifuge was performed, a supernatant was discarded, and the resultant was dissolved in 5 ml of toluene.

### Step 2: Preparation of Core/Middle Shell Quantum Dot of InP/ZnSe/ZnS (InP/ZnSe/ZnS Quantum Dot)

2.3 g of zinc acetate, 5 ml of oleic acid and 10 ml of TOP were mixed to prepare a Zn-oleate precursor. 1 mmol of Se, 4.5 mmol of S, 3 ml of oleic acid, 5 ml of 1-octadecene, 5 ml of the Zn-oleate precursor and 1 ml of the synthesized InP core (in toluene) were put in a three neck flask, and moisture and oxygen were removed while stirring at about 120° C. for about 30 minutes. After that, N₂ purge was performed, and the temperature was raised to about 160° C. 1 ml of a Se-TOP precursor solution obtained by dissolving 0.8 mmol of Se powder in 2 ml of TOP was injected thereto, and the temperature of the reactants was raised to about 270° C., followed by reacting for about 30 minutes. 2 ml of the Se-TOP precursor solution was additionally injected to the reaction solution, and the temperature was maintained for about 10 minutes. The temperature of the reactants was reduced to about 180° C., a S-TOP precursor solution obtained by dissolving 0.8 mmol of S powder in 2 ml of TOP was injected, and the temperature was raised to about 280° C. After reacting for about 30 minutes, 2 ml of the S-TOP precursor solution was additionally injected, the temperature was maintained for about 30 minutes, and the reaction was finished.

### Step 3: Formation of Shell

0.8 ml of the InP/ZnSe/ZnS quantum dot synthesized in step 2 (concentration: 100 mg/ml in cyclohexane), 0.64 ml of tetraethyl orthosilicate (TEOS), 15 ml of cyclohexane and 1 ml of Igepal co-630 were put in a flask, and stirred for about 1 hour. 0.2 ml of ammonia (32%) was added thereto, followed by stirring for about 4 hours. 2.5 ml of 3-aminopropyl-trimethoxysilane (APS) was put, followed by stirring for about 1 hour. In order to purify the synthesized particles, the resultant was centrifuged at about 9000 rpm for about 10 minutes, a supernatant was discarded, and 3 ml of isopropanol was added for dispersing.

### Step 4: Formation of Nanoparticles

To the quantum dot-shell solution synthesized in step 3, 10 ml of Ag nanoparticles with a size of about 7 nm (concentration: 10 mg/ml in isopropanol) was added, and stirred for about 2 hours to form a quantum dot complex. In order to purify the quantum dot complex thus formed, a centrifuge was operated at about 9000 rpm for about 10 minutes, a supernatant was discarded, and 3 ml of acetone was added for dispersing.

### 2) Comparative Example

A quantum dot complex was prepared by a same method as the Example except for omitting step 3 and step 4 in the Example.

### (Preparation of Quantum Dot Composition)

### 1) Example 1-1

### Step 1: Quantum Dot Complex Ligand Modification

5 ml of a quantum dot complex (20 wt % in chloroform) and 0.1 ml of mPEG3-triethoxysilane were added to a vial and stirred at about 60° C. for about 2 hours. 0.1 ml of mPEG4-SH was additionally added thereto, and stirring was performed for about 1 hour. After precipitating, 30 ml of hexane was added for purification, and a centrifuge was operated at about 9000 rpm for about 3 minutes, and a supernatant was discarded.

### Step 2: Preparation of Quantum Dot Composition

55 wt % of hexamethylene diacrylate, 4 wt % of TiO₂ (average particle diameter of about 180 nm), 1 wt % of an initiator (TPO (ethyl(2,4,6-trimethoxybenzoyl)phenylphosphinate)) and 40 wt % of the quantum dot complex (QD/SiO₂/Ag) prepared in step 1 above were added and stirred for about 12 hours to prepare a quantum dot composition.

A quantum dot composition was prepared by a same method as Example 1-1 except for changing the content of the quantum dot complex to about 35 wt % on the basis of the total content of the quantum dot composition.

### 2) Example 1-2

### 3) Example 1-3

A quantum dot composition was prepared by a same method as Example 1-1 except for changing the content of the quantum dot complex to about 25 wt % on the basis of the total content of the quantum dot composition.

### 4) Comparative Example 1-1

A quantum dot composition was prepared by a same method as Example 1-1 except for using the quantum dot complex of the Comparative Example.

### 5) Comparative Example 1-2

A quantum dot composition was prepared by a same method as Example 1-2 except for using the quantum dot complex of the Comparative Example.

### 6) Comparative Example 1-3

A quantum dot composition was prepared by a same method as Example 1-3 except for using the quantum dot complex of the Comparative Example.

### 2. Formation of Light Conversion Pattern

Light conversion single layers films were formed using the quantum dot compositions prepared in Example 1-1 to Example 1-3, and Preparation Comparative Example 1-1 to Comparative Example 1-3. The quantum dot compositions prepared were discharged on an organic substrate by an inkjet method to form films, exposed and cured to form light conversion patterns with a thickness of about 10 μm.

In Table 1, the external quantum efficiency (EQE) and viscosity according to the Examples and the Comparative Examples were measured and shown. In order to evaluate the properties of the light conversion patterns formed from Example 1-1 to Example 1-3, and Comparative Example 1-1 to Comparative Example 1-3, the external quantum efficiency was obtained by measuring external quantum efficiency at a current density of about 1000 cd/m² using a quantum efficiency measurement apparatus (QE2100, Otsuka Co.). The viscosity was measured using LVDV-II+P (BROOKFIELD Co.).

In Table 1, with respect to the light conversion patterns formed in the Examples and Comparative Examples, excited light in a wavelength of about 450 nm was irradiated, and the external quantum efficiency was measured and shown. In an embodiment, the external quantum efficiency may be calculated according to Equation 1 below.

$$External quantum efficiency = {N}_{1} / {N}_{2} \times 100 \qquad [ Equation 1 ]$$

In Equation 1, N₁ may be a number of photons emitted from the quantum dot complex, and N₂ may be a number of photons of excited light provided to the quantum dot complex.

TABLE 1

| | | External quantum |
|---|---|---|
| Division | Viscosity (cps) | efficiency (%) |
| Example 1-1 | 25 | 37 |
| Example 1-2 | 19 | 35 |
| Example 1-3 | 12 | 30 |
| Comparative Example 1-2 | 28 | 33 |
| Comparative Example 1-2 | 22 | 27 |
| Comparative Example 1-3 | 17 | 20 |

Referring to the results of Table 1, it can be confirmed that the Examples exhibited high external quantum efficiency in contrast to the content of the quantum dot complex used compared to the Comparative Examples. Referring to Example 1-1 to Example 1-3, it can be confirmed that the contents of the quantum dot complexes used for the preparation of the quantum dot compositions decreased toward about 45 wt %, about 35 wt % and about 25 wt %, and the viscosity was low, but all Example 1-1 to Example 1-3 showed high external quantum efficiency of about 30% or higher. In contrast, referring to Comparative Example 1-1 to Comparative Example 1-3, it can be confirmed that the external quantum efficiency was significantly reduced with the decrease of the contents of the quantum dot complexes in the quantum dot compositions toward about 45 wt %, about 35 wt % and about 25 wt %, compared to the Examples. Particularly, if comparing Example 1-3 and Comparative Example 1-3, Example 1-3 and Comparative Example 1-3 each includes a same content of the quantum dot complex of about 25 wt %, but it can be confirmed that Example 1-3 showed lower viscosity but higher external quantum efficiency by about 10% compared to Comparative Example 1-3. The quantum dot complexes of the Examples include a quantum dot, a shell surrounding the quantum dot, and nanoparticles disposed on the surface of the shell, and showed improved luminous intensity due to surface plasmon resonance phenomenon due to the nanoparticles. Accordingly, though the quantum dot complex is included in the small content in the quantum dot composition, the external quantum efficiency may be maintained high, and the luminous efficiency of the light control pattern formed therefrom may be improved. Due to the improved luminous intensity, the content of the quantum dot complex in the quantum dot composition may be reduced, and the viscosity of the quantum dot composition may be maintained low, and solution processability may also be improved.

According to an embodiment of the disclosure, a quantum dot complex capable of having high quantum efficiency may be provided.

According to an embodiment of the disclosure, a display device having improved luminous efficiency properties by including a quantum dot showing high quantum efficiency may be provided.

According to an embodiment of the disclosure, a method for manufacturing a display device which has excellent luminous efficiency and process reliability may be provided.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A quantum dot complex comprising:
a quantum dot;
a shell surrounding the quantum dot; and
nanoparticles bonded to a surface of the shell and comprising silver.

2. The quantum dot complex of claim 1, wherein a thickness of the shell is in a range of about 10 nm to about 50 nm.

3. The quantum dot complex of claim 1, wherein the shell comprises at least one of a metal oxide and a polymer compound.

4. The quantum dot complex of claim 1, wherein the shell comprises at least one of SiO₂, TiO₂, and polymethyl methacrylate (PMMA).

5. The quantum dot complex of claim 1, wherein a maximum absorption wavelength range of the nanoparticle is in a range of about 400 nm to about 450 nm.

6. The quantum dot complex of claim 1, wherein a full width of half maximum of a maximum absorption wavelength range of the nanoparticle is in a range of about 80 nm to about 120 nm.

7. The quantum dot complex of claim 1, wherein a maximum emission wavelength range of the quantum dot is in a range of about 510 nm to about 550 nm.

8. The quantum dot complex of claim 1, wherein the quantum dot comprises a core, and a middle shell surrounding the core.

9. The quantum dot complex of claim 8, wherein
the core comprises a first semiconductor nanocrystal,
the middle shell comprises a second semiconductor nanocrystal different from the first semiconductor nanocrystal, and
each of the first semiconductor nanocrystal and the second semiconductor nanocrystal includes at least one of a group II-VI compound, a group III-VI compound, a group I-III-VI compound, a group III-V compound, a group III-II-V compound, a group IV-VI compound, a group IV element, a group IV compound, and a combination thereof.

10. The quantum dot complex of claim 8, wherein the core comprises InP or AgInGaS.

11. The quantum dot complex of claim 8, wherein
the middle shell comprises:
a first middle shell surrounding the core; and
a second middle shell surrounding the first middle shell, and
each of the first middle shell and the second middle shell comprises a group III-VI compound.

12. A method for manufacturing a display device, the method comprising:
preparing a display panel; and
forming a light control layer on the display panel by forming multiple light control parts, wherein
the forming of at least one of the multiple light control parts comprises:
providing a quantum dot composition comprising a base resin and a quantum dot complex dispersed in the base resin to form a preliminary light control part; and
curing the preliminary light control part, and
the quantum dot complex comprises:
a quantum dot;
a shell surrounding the quantum dot; and
nanoparticles bonded to a surface of the shell and comprising silver.

13. The method for manufacturing a display device of claim 12, wherein a viscosity of the quantum dot composition is less than or equal to about 25 cps.

14. The method for manufacturing a display device of claim 12, further comprising:
forming a preliminary light control member after the curing of the preliminary light control part; and
exposing the preliminary light control part to excited light in a wavelength of about 450 nm,
wherein after the exposing of the preliminary light control part, an external quantum efficiency (EQE) is greater than or equal to about 30%.

15. The method for manufacturing a display device of claim 12, wherein a content of the quantum dot complex is in a range of about 20 wt % to about 45 wt % on a basis of a total quantum dot composition content.

16. The method for manufacturing a display device of claim 12, wherein a thickness of the shell is in a range of about 10 nm to about 50 nm.

17. The method for manufacturing a display device of claim 12, wherein the shell comprises at least one of SiO₂, TiO₂, and polymethyl methacrylate (PMMA).

18. The method for manufacturing a display device of claim 12, wherein a maximum absorption wavelength range of the nanoparticle is in a range of about 400 nm to about 450 nm.

19. A display device comprising:
a display panel; and
a light conversion layer disposed on the display panel and comprising multiple light control parts, wherein
at least one of the multiple light control parts comprises a quantum dot complex, and
the quantum dot complex comprises:
a quantum dot;
a shell surrounding the quantum dot; and
nanoparticles bonded to a surface of the shell and comprising silver.

20. The display device of claim 19, wherein
the display panel comprises a light emitting element producing first light, and
the multiple light control parts comprise:
a first light control part transmitting the first light;
a second light control part converting the first light into second light; and
a third light control part converting the first light into third light.
